(19) United States
(12) Patent Application Publication
(10) Pub. No.: US 2022/0399469 A1
(43) Pub. Date: Dec. 15, 2022

(54) LIGHT RECEIVING ELEMENT, LIGHT RECEIVING ELEMENT MANUFACTURING METHOD, AND SOLID-STATE IMAGE PICKUP APPARATUS

(71) Applicant: SONY SEMICONDUCTOR SOLUTIONS CORPORATION, KANAGAWA (JP)

(72) Inventor: HIDEKI MINARI, TOKYO (JP)

(21) Appl. No.: 17/755,202

(22) PCT Filed: Sep. 24, 2020
(86) PCT No.: PCT/JP2020/036060

§ 371 Date: Apr. 22, 2022

(30) Foreign Application Priority Data
Oct. 30, 2019 (JP) 2019-197057

(51) Int. Cl. H01L 31/105

(52) U.S. Cl. CPC H01L 31/105; H01L 31/18

(57) ABSTRACT

A light receiving element that has a structure in which p-n junctions contact the interface between a compound semiconductor material and an insulating film and that can reduce a dark current is provided. A light receiving element includes a plurality of pixels. Each of the plurality of pixels includes a light absorption layer that has a first surface from which light enters and that includes a compound semiconductor material, a first-conductivity-type first semiconductor layer that is provided on a side of a second surface of the light absorption layer, the second surface being opposite to the first surface, and has bandgap energy greater than that of the light absorption layer, a second-conductivity-type selection region that is provided in such a manner as to reach the light absorption layer from a second surface of the first semiconductor layer, the second surface being opposite to a first surface on a side of the light absorption layer, and contacts the first semiconductor layer, a first insulating film that is provided on a side of the second surface of the first semiconductor layer and contacts the first semiconductor layer and the selection region, and a first electrode provided, for each of the pixels, on the side of the second surface of the first semiconductor layer. The first insulating film has a non-volatile electric charge with a same polarity as that of one of the semiconductor layer and the selection region that has a higher mobile charge density.

### TECHNICAL FIELD

The technology according to the present disclosure (the present technology) relates to a light receiving element, a light receiving element manufacturing method, and a solid-state image pickup apparatus using a light receiving element.

### BACKGROUND ART

Light receiving elements (InGaAs sensors) using indium gallium arsenide (InGaAs) crystals epitaxially grown on an indium phosphide (InP) substrate can detect short-wavelength infrared light, and thus have been under study and development mainly for the purpose of monitoring and military uses. Light receiving elements have p-n junctions or pin junctions, and are capable of optical detection by performing what is generally called semiconductor photodiode operation of obtaining signals by reading out changes of currents and voltages accompanying generation of electrons and holes at the time of light irradiation. Because bandgap energy of InGaAs that lattice-matches with InP is 0.75 eV, which is smaller than bandgap energy of silicon (Si), InGaAs can detect light with a long wavelength in the short-wavelength infrared region.

In order to obtain an image by using a light receiving element, it is necessary to arrange photodiodes in an array all over the light receiving element, and in order to acquire independently each signal of the plurality of photodiodes arranged, adjacent photodiodes, that is, adjacent pixels, are electrically separated from each other. As a method of realizing electrical separation of contact sections in an InGaAs sensor, a selective diffusion process of diffusing a dopant selectively only to the contact sections is used in many cases (see PTL 1 and PTL 2).

### CITATION LIST

### Patent Literature

### [PTL 1]

JP Sho 63-304664A

### [PTL 2]

JP Sho 59-222972A

### SUMMARY

### Technical Problem

However, in a case where a selective diffusion process is used to form contact sections, p-n junctions including, as parts thereof, the contact sections come into contact with the interface between a compound semiconductor material and an insulating film. Typically, there are many defects at the interface between the compound semiconductor material and the insulating film, and if a p-n junction depletion layer comes into contact with the interface, generation of an electric charge due to the interface defect level increases. The generated electric charge flows into the contact sections as a dark current, and the noise characteristics of the image sensor deteriorate.

An object of the present technology is to provide a light receiving element, a light receiving element manufacturing method, and a solid-state image pickup apparatus using a light receiving element that make it possible to reduce a dark current in a structure in which p-n junctions contact the interface between a compound semiconductor material and an insulating film.

### Solution to Problem

To summarize, a light receiving element according to an aspect of the present technology includes a plurality of pixels. Each of the plurality of pixels includes a light absorption layer that has a first surface from which light enters and that includes a compound semiconductor material, a first-conductivity-type first semiconductor layer that is provided on a side of a second surface of the light absorption layer, the second surface being opposite to the first surface, and has bandgap energy greater than that of the light absorption layer, a second-conductivity-type selection region that is provided in such a manner as to reach the light absorption layer from a second surface of the first semiconductor layer, the second surface being opposite to a first surface on a side of the light absorption layer, and contacts the first semiconductor layer, a first insulating film that is provided on a side of the second surface of the first semiconductor layer and contacts the first semiconductor layer and the selection region, and a first electrode provided, for each of the pixels, on the side of the second surface of the first semiconductor layer. The first insulating film has a non-volatile electric charge with a same polarity as that of one of the semiconductor layer and the selection region that has a higher mobile charge density.

To summarize, a light receiving element manufacturing method according to an aspect of the present technology includes forming a first-conductivity-type first semiconductor layer having bandgap energy greater than a light absorption layer that has a first surface from which light enters and that includes a compound semiconductor material, the first semiconductor layer being formed on a side of a second surface of the light absorption layer, the second surface being opposite to the first surface, forming a second-conductivity-type selection region in such a manner as to reach the light absorption layer from a second surface of the first semiconductor layer, the second surface being opposite to a first surface on a side of the light absorption layer, and additionally contact the first semiconductor layer, forming, on a side of the second surface of the first semiconductor layer, a first insulating film having a non-volatile electric charge with a same polarity as that of one of the first semiconductor layer and the selection region that has a higher mobile charge density such that the first insulating film contacts the first semiconductor layer and the selection region, and forming, for each of the pixels, a first electrode on the side of the second surface of the first semiconductor layer.

To summarize, a solid-state image pickup apparatus according to an aspect of the present technology includes a pixel region including a plurality of pixels and a circuit section that controls the pixel region. Each of the plurality of pixels includes a light absorption layer that has a first surface from which light enters and that includes a compound semiconductor material, a first-conductivity-type first semiconductor layer that is provided on a side of a second surface of the light absorption layer, the second surface being opposite to the first surface, and has bandgap energy greater than that of the light absorption layer, a second-conductivity-type selection region that is provided in such a manner as to reach the light absorption layer from a second surface of the first semiconductor layer, the second surface being opposite to a first surface on a side of the light absorption layer, and contacts the first semiconductor layer, a first insulating film that is provided on a side of the second surface of the first semiconductor layer and contacts the first semiconductor layer and the selection region, and a first electrode provided, for each of the pixels, on the side of the second surface of the first semiconductor layer. The first insulating film has a non-volatile electric charge with a same polarity as that of one of the semiconductor layer and the selection region that has a higher mobile charge density.

### BRIEF DESCRIPTION OF DRAWINGS

FIG. 1 is a block diagram of a solid-state image pickup apparatus according to a first embodiment.

FIG. 2 is a schematic diagram of the solid-state image pickup apparatus according to the first embodiment.

FIG. 3 is a plan view of a pixel region according to the first embodiment.

FIG. 4 is a cross-sectional view as seen in a direction A-A in FIG. 3.

FIG. 5 is a partially enlarged view of a region A1 in FIG. 4.

FIG. 6 is a cross-sectional view of pixels according to a comparative example.

FIG. 7 is a partially enlarged view of a region A2 in FIG. 6.

FIG. 8 is a schematic diagram of device simulation results of an implementation example.

FIG. 9 is a schematic diagram of device simulation results of a comparative example.

FIG. 10 is a graph depicting a relation between a surface recombination velocity and a dark current in a case where a fixed electric charge of an insulating film is changed.

FIG. 11 is a cross-sectional view of a step of a pixel manufacturing method according to the first embodiment.

FIG. 12 is a cross-sectional view of a step next to FIG. 11 in the pixel manufacturing method according to the first embodiment.

FIG. 13 is a cross-sectional view of a step next to FIG. 12 in the pixel manufacturing method according to the first embodiment.

FIG. 14 is a cross-sectional view of a step next to FIG. 13 in the pixel manufacturing method according to the first embodiment.

FIG. 15 is a cross-sectional view of a step next to FIG. 14 in the pixel manufacturing method according to the first embodiment.

FIG. 16 is a cross-sectional view of a step next to FIG. 15 in the pixel manufacturing method according to the first embodiment.

FIG. 17 is a cross-sectional view of a step next to FIG. 16 in the pixel manufacturing method according to the first embodiment.

FIG. 18 is a cross-sectional view of a step next to FIG. 17 in the pixel manufacturing method according to the first embodiment.

FIG. 19 is a cross-sectional view of pixels according to a second embodiment.

FIG. 20 is a partially enlarged view of a region A3 in FIG. 19.

FIG. 21 is a cross-sectional view of a step of a pixel manufacturing method according to the second embodiment.

FIG. 22 is a cross-sectional view of a step next to FIG. 21 in the pixel manufacturing method according to the second embodiment.

FIG. 23 is a cross-sectional view of a step next to FIG. 22 in the pixel manufacturing method according to the second embodiment.

FIG. 24 is a cross-sectional view of a step next to FIG. 23 in the pixel manufacturing method according to the second embodiment.

FIG. 25 is a cross-sectional view of a step next to FIG. 24 in the pixel manufacturing method according to the second embodiment.

FIG. 26 is a cross-sectional view of a step next to FIG. 25 in the pixel manufacturing method according to the second embodiment.

FIG. 27 is a cross-sectional view of a step next to FIG. 26 in the pixel manufacturing method according to the second embodiment.

FIG. 28 is a cross-sectional view of pixels according to a third embodiment.

FIG. 29 is a partially enlarged view of a region A4 in FIG. 28.

FIG. 30 is a cross-sectional view of a step of a pixel manufacturing method according to the third embodiment.

FIG. 31 is a cross-sectional view of a step next to FIG. 30 in the pixel manufacturing method according to the third embodiment.

FIG. 32 is a cross-sectional view of a step next to FIG. 31 in the pixel manufacturing method according to the third embodiment.

FIG. 33 is a cross-sectional view of a step next to FIG. 32 in the pixel manufacturing method according to the third embodiment.

FIG. 34 is a cross-sectional view of a step next to FIG. 33 in the pixel manufacturing method according to the third embodiment.

FIG. 35 is a cross-sectional view of a step next to FIG. 34 in the pixel manufacturing method according to the third embodiment.

FIG. 36 is a cross-sectional view of a step next to FIG. 35 in the pixel manufacturing method according to the third embodiment.

FIG. 37 is a cross-sectional view of a step next to FIG. 36 in the pixel manufacturing method according to the third embodiment.

FIG. 38 is a cross-sectional view of pixels according to a fourth embodiment.

FIG. 39 is a partially enlarged view of a region A5 in FIG. 38.

FIG. 40 is a cross-sectional view of pixels according to the fifth embodiment.

FIG. 41 is a cross-sectional view of pixels according to a sixth embodiment.

FIG. 42 is a block diagram of electronic equipment using the solid-state image pickup apparatus.

FIG. 43 is a view depicting an example of a schematic configuration of an endoscopic surgery system.

FIG. 44 is a block diagram depicting an example of a functional configuration of a camera head and a camera control unit (CCU).

FIG. 45 is a block diagram depicting an example of schematic configuration of a vehicle control system.

FIG. 46 is a diagram of assistance in explaining an example of installation positions of an outside-vehicle information detecting section and an imaging section.

### DESCRIPTION OF EMBODIMENTS

First to sixth embodiments of the present technology are explained below with reference to the figures. In the descriptions of the figures referred to in the explanation below, identical or similar portions are given identical or similar reference signs. However, it should be noted that the figures are schematic figures and the relation between a thickness and planar dimensions, the ratio between the thicknesses of layers, and the like are different from actual ones. Accordingly, specific thicknesses and dimensions should be determined taking the explanation below into consideration. In addition, needless to say, the dimensional relations or ratios between figures do not necessarily reflect actual relations or ratios. Note that advantages described in the present specification are depicted merely as examples and are not the sole advantages. In addition, there may be other advantages.

In the present specification, a “first conductivity type” means one of a p type or an n type, and a “second conductivity type” means the other of the p type or the n type which is different from the “first conductivity type.” In addition, “+” or “−” given to “n” or “p” means that a semiconductor region corresponding to the “+” or “−” has an impurity density which is relatively higher than or lower than the impurity density of a semiconductor region not given “+” or “−,” respectively. It should be noted that even if semiconductor regions are given the same “n,” this does not mean that the impurity densities of the semiconductor regions are strictly the same.

In addition, the definitions of directions such as “upper,” “lower,” and the like in the explanation below are simply definitions for convenience of explanation and do not limit the technical idea of the present technology. For example, needless to say, if an object is observed after being rotated 90°, “upper” and “lower” are read as having converted meanings “left” and “right,” and if the object is observed after being rotated 180°, “upper” and “lower” are read as meaning opposite directions.

### First Embodiment

<Overall Configuration of Solid-State Image Pickup Apparatus>

For example, a solid-state image pickup apparatus according to a first embodiment can be applied to an infrared sensor or the like that uses a compound semiconductor material such as a group III-V semiconductor. For example, the solid-state image pickup apparatus has a functionality of photoelectrically converting light having a wavelength in the visible region approximately from 380 nm inclusive to 780 nm not inclusive into light having a wavelength up to the short-wavelength infrared region approximately from 780 nm inclusive to 2400 nm not inclusive.

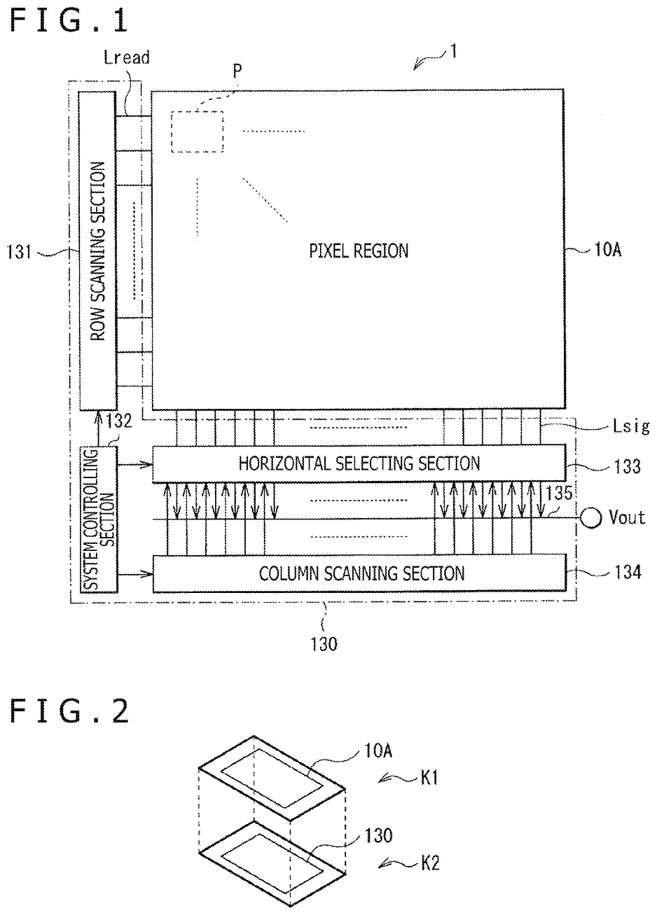

As depicted in FIG. 1, a solid-state image pickup apparatus 1 according to the first embodiment has a pixel region 10A and a circuit section 130 that drives the pixel region 10A. For example, the circuit section 130 has a row scanning section 131, a horizontal selecting section 133, a column scanning section 134, and a system controlling section 132.

For example, the pixel region 10A has a plurality of pixels P that are arranged in a two-dimensional matrix. For the pixels P, for example, a pixel driving line Lread (e.g. a row selection line and a reset control line) is placed for each pixel row, and a vertical signal line Lsig is placed for each pixel column. The pixel driving lines Lread transfer drive signals for signal reading from the pixels P. An end of a pixel driving line Lread is connected to an output terminal of the row scanning section 131 corresponding to each row.

The row scanning section 131 includes a shift register, an address decoder, and the like. For example, the row scanning section 131 drives pixels P in the pixel region 10A in units of a row of pixels P. A signal output from each pixel P in a pixel row, the pixel P being selected and scanned by the row scanning section 131, is supplied to the horizontal selecting section 133 through one of the vertical signal lines Lsig. The horizontal selecting section 133 includes an amplifier, a horizontal selection switch, and the like provided for each vertical signal line Lsig.

The column scanning section 134 includes a shift register, an address decoder, and the like. The column scanning section 134 drives the horizontal selection switches of the horizontal selecting section 133 while scanning each of them sequentially. Due to the selective scanning by the column scanning section 134, a signal of each pixel transferred through one of the vertical signal lines Lsig is output to a horizontal signal line 135 sequentially, and is output via the horizontal signal line 135 to a signal processing section or the like which is not depicted.

The system controlling section 132 receives a clock, data which is a command about an operation mode, and the like from the outside, and, in addition, outputs data such as internal information of the solid-state image pickup apparatus 1. Further, the system controlling section 132 has a timing generator that generates various types of timing signals, and, on the basis of the various types of timing signals generated at the timing generator, performs drive control of the row scanning section 131, the horizontal selecting section 133, the column scanning section 134, and the like.

As depicted in FIG. 2, for example, the solid-state image pickup apparatus 1 may have a configuration in which an element substrate K1 having the pixel region 10A and a circuit substrate K2 having the circuit section 130 are stacked one on another. Note that the configuration of the solid-state image pickup apparatus 1 is not limited to the configuration depicted in FIG. 2. For example, the circuit section 130 may be formed on the same substrate as the one on which the pixel region 10A is formed or may be disposed in an external control IC. In addition, the circuit section 130 may be formed in another substrate connected by a cable or the like. In addition, the solid-state image pickup apparatus 1 may include three or more substrates.

<Configuration of Pixels>

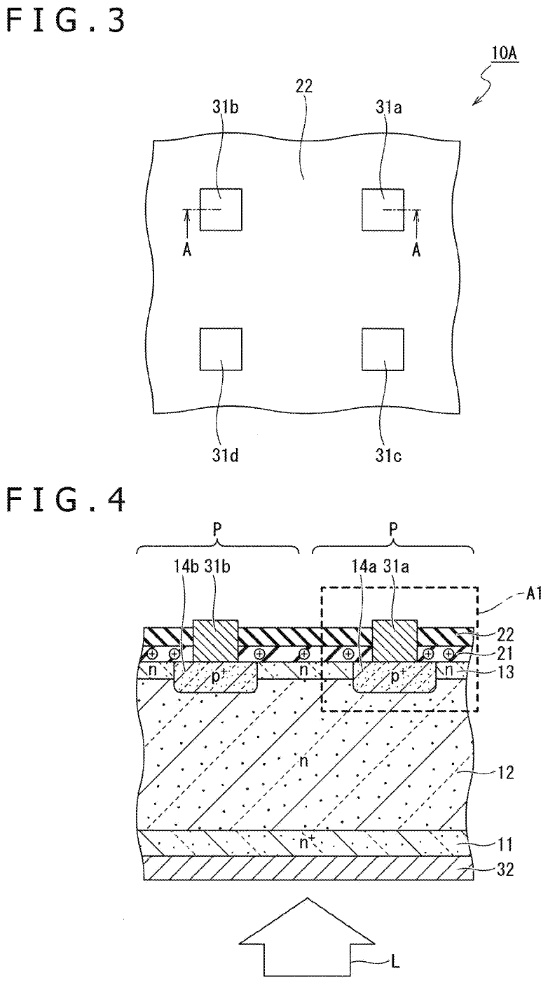

FIG. 3 is a plan view of a part of the pixel region 10A. As depicted in FIG. 3, a plurality of first electrodes 31a, 31b, 31c, and 31d each of which corresponds to one of the plurality of pixels P are arranged in a matrix. A cross-section of two pixels P as seen in a direction A-A in FIG. 3 is depicted in FIG. 4.

The pixels P include an n-type light absorption layer (photoelectric conversion layer) 12, an n-type semiconductor layer 13 provided on a second surface (upper surface) of the light absorption layer 12, the second surface being opposite to a first surface (lower surface) from which light L enters, and p⁺-type selection regions 14a and 14b provided in such a manner as to reach the light absorption layer 12 from a second surface (upper surface) of the semiconductor layer 13, the second surface being opposite to a first surface (lower surface) on the side of the light absorption layer 12.

The light absorption layer 12 shared by the plurality of pixels P is provided. The light absorption layer 12 absorbs light with a predetermined wavelength such as a wavelength in a region from the visible region to the short-wavelength infrared region or the like, and generates a signal charge by photoelectric conversion. The light absorption layer 12 includes a compound semiconductor material. For example, as the compound semiconductor material included in the light absorption layer 12, at least a group III-V semiconductor including at least any one of indium (In), gallium (Ga), aluminum (Al), arsenic (As), phosphorus (P), antimony (Sb), and nitrogen (N) and a group IV semiconductor including at least any one of silicon (Si), carbon (C), and germanium (Ge) can be used. Examples of the compound semiconductor material included in the light absorption layer 12 specifically include indium gallium arsenide (InGaAs), indium gallium arsenide phosphide (InGaAsP), indium arsenide antimonide (InAsSb), indium gallium phosphide (InGaP), gallium arsenide antimonide (GaAsSb), indium aluminum arsenide (InAlAs), gallium nitride (GaN), silicon carbide (SiC), silicon germanium (SiGe), and the like.

For example, InGaAs, SiGe, and the like are narrow bandgap semiconductors having bandgap energy smaller than Si, and have light absorption sensitivity to the infrared light region on the longer-wavelength side of the visible light region. In addition, GaN and the like are wide bandgap semiconductors having bandgap energy greater than Si, and have light absorption sensitivity to the ultraviolet light region on the shorter-wavelength side of the visible light region. The material of the light absorption layer 12 can be selected as appropriate according to a target wavelength region or the like. For example, the impurity density of the light absorption layer 12 is approximately 1×10¹³ to 1×10¹⁸ cm⁻³. For example, the thickness of the light absorption layer 12 is approximately 100 to 10000 nm.

The semiconductor layer 13 can include a compound semiconductor material having bandgap energy greater than that of the compound semiconductor material included in the light absorption layer 12. For example, in a case where the light absorption layer 12 includes InGaAs having bandgap energy which is 0.75 eV, indium phosphide (InP) having bandgap energy which is 1.35 eV can be used for the semiconductor layer 13. For example, as the compound semiconductor material included in the semiconductor layer 13, at least a group III-V semiconductor including any one of In, Ga, Al, As, P, Sb, and N and a group IV semiconductor including at least any one of Si, C, and Ge can be used. Specifically, other than InP, examples include InGaAsP, InAsSb, InGaP, GaAsSb and InAlAs, GaN, SiC, SiGe, and the like. For example, the thickness of the semiconductor layer 13 is approximately 200 to 5000 nm.

The selection regions 14a and 14b function as contact sections of the pixels P. The selection regions 14a and 14b are provided over the semiconductor layer 13 and the light absorption layer 12 such that the selection regions 14a and 14b straddle and contact the light absorption layer 12 and the semiconductor layer 13. The interface between the semiconductor layer 13 and the light absorption layer 12 in the pixels P is surrounded by the selection regions 14a and 14b. For example, the selection regions 14a and 14b have rectangular planar patterns. For example, the selection regions 14a and 14b include diffusion regions in which p-type impurities such as zinc (Zn) are diffused by a selective diffusion process.

As the impurities diffused in the selection regions 14a and 14b, other than Zn, magnesium (Mg), cadmium (Cd), beryllium (Be), silicon (Si), germanium (Ge), carbon (C), tin (Sn), lead (Pb), sulfur (S) or tellurium (Te), phosphorus (P), boron (B), arsenic (As), indium (In), antimony (Sb), gallium (Ga), aluminum (Al), or the like may be used. For example, the impurity density of the selection regions 14a and 14b is approximately 1×10¹⁶ to 1×10¹⁹ cm⁻³. The p⁺-type selection regions 14a and 14b are included in p-n junctions along with the n-type semiconductor layer 13.

On the side of the second surface (upper surface) of the semiconductor layer 13, a first insulating film 21 is provided in such a manner as to contact the semiconductor layer 13 and the selection regions 14a and 14b. The first insulating film 21 covers each of the p-n junctions including the semiconductor layer 13 and one of the selection regions 14a and 14b. For example, the thickness of the first insulating film 21 is approximately 10 to 10000 nm. The first insulating film 21 has a positive or negative fixed electric charge. The “fixed electric charge” means a non-volatile electric charge. In addition, a “positive fixed electric charge” means a non-volatile hole, and a “negative fixed electric charge” means a non-volatile electron. The positive or negative fixed electric charge of the first insulating film 21 can be introduced intentionally, and can be adjusted as appropriate according to the material of the first insulating film 21, a surface treatment on the base layer of the first insulating film 21, film-formation conditions of the first insulating film 21, and the like.

Here, the first insulating film 21 has a fixed electric charge with the same polarity as that (those) of one(s) which is or are either the semiconductor layer 13 or the selection regions 14a and 14b included in the p-n junctions covered with the first insulating film 21 and which has or have a higher mobile charge density. That is, in a case where an acceptor density N_{A} of the p-type region forming the p-n junctions is higher than a donor density N_{D} of the n-type region (in a case where N_{A} > N_{D}), the first insulating film 21 has positive fixed electric charges (holes). On the other hand, in a case where the acceptor density N_{A} of the p-type region is lower than the donor density N_{D} of the n-type region (in a case where N_{A}<N_{D}), the first insulating film 21 has negative fixed electric charges (electrons).

In the case explained in the first embodiment, the acceptor density N_{A} of the p-type selection regions 14a and 14b forming the p-n junctions is higher than the donor density N_{D} of the n-type semiconductor layer 13 (N_{A} > N_{D}). In this case, as depicted in FIG. 4, the first insulating film 21 has positive fixed electric charges (holes) with the same polarity as those of the selection regions 14a and 14b. In FIG. 4, holes accumulated in the first insulating film 21 are depicted schematically.

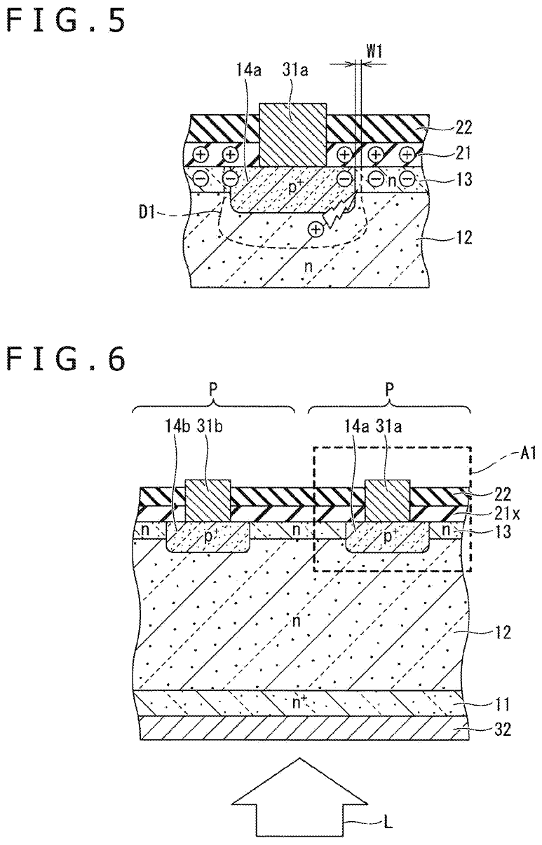

As depicted in FIG. 5, electrons are thereby induced near the interface of the n-type semiconductor layer 13 facing the first insulating film 21, and a width W1 of a p-n junction depletion layer D1 is reduced. Therefore, a dark current generated in the depletion layer D1 can be reduced. In FIG. 5, the depletion layer D1 is depicted schematically by a broken line. In addition, FIG. 5 schematically depicts holes accumulated in the first insulating film 21, electrons induced in the semiconductor layer 13, and holes to be a dark current in the depletion layer D1. At this time, electrons are induced also near the interface of the p-type selection regions 14a and 14b facing the first insulating film 21, but because the selection regions 14a and 14b have a higher p-type impurity density, the electrons are cancelled out by the holes, and do not influence the p-n junction width and the dark current generation amount.

On the other hand, although not depicted, in a case where the acceptor density N_{A} of the p-type selection regions 14a and 14b forming the p-n junctions is lower than the donor density N_{D} of the n-type semiconductor layer 13 (in a case where N_{A}<N_{D}), the first insulating film 21 has negative fixed electric charges (electrons) with the same polarity as that of the semiconductor layer 13. Holes are thereby induced near the interface of the n-type semiconductor layer 13 facing the first insulating film 21, and the width W1 of the p-n junction depletion layer D1 is reduced. Therefore, a dark current generated in the depletion layer D1 can be reduced.

The first insulating film 21 is an insulator material including at least any one of at least silicon (Si), nitrogen (N), aluminum (Al), hafnium (Hf), tantalum (Ta), titanium (Ti), oxygen (O), magnesium (Mg), scandium (Sc), zirconium (Zr), lanthanum (La), gadolinium (Gd), and yttrium (Y). Specifically, the first insulating film 21 may include a silicon nitride (Si₃N₄) film, an aluminum oxide (Al₂O₃) film, a silicon oxide (SiO₂) film, a silicon oxynitride (SiON) film, an aluminum oxynitride (AlON) film, a silicon aluminum nitride (SiAlN) film, a magnesium oxide (MgO) film, an aluminum silicon oxide (AlSiO) film, a hafnium oxide (HfO₂) film, a hafnium aluminum oxide (HfAlO) film, a tantalum oxide (Ta₂O₃) film, a titanium oxide (TiO₂) film, a scandium oxide (Sc₂O₃) film, a zirconium oxide (ZrO₂) film, a gadolinium oxide (Gd₂O₃) film, a lanthanum oxide (La₂O₃) film, an yttrium oxide (Y₂O₃) film, or the like.

As depicted in FIG. 4, a second insulating film 22 is provided on a second surface (upper surface) of the first insulating film 21, the second surface being opposite to the first surface (lower surface) on the side of the semiconductor layer 13. For example, the thickness of the second insulating film 22 is approximately 10 to 10000 nm. The second insulating film 22 may have a positive or negative fixed electric charge or may not have a fixed electric charge.

The second insulating film 22 is an insulator material including any one of at least Si, N, Al, Hf, Ta, Ti, O, Mg, Sc, Zr, La, Gd, and Y. For example, the second insulating film 22 may include a Si₃N₄ film, an Al₂O₃ film, a SiO₂ film, a SiON film, an AlON film, a SiAlN film, a MgO film, an AlSiO film, a HfO₂ film, a HfAlO film, a Ta₂O₃ film, a TiO₂ film, a Sc₂O₃ film, a ZrO₂ film, a Gd₂O₃ film, a La₂O₃ film, an Y₂O₃ film, or the like.

The second insulating film 22 may include the same material as that of the first insulating film 21 or may include a different material. The second insulating film 22 may not be included in the configuration or an insulating film or a protective film may be stacked further on the second insulating film 22.

On the side of the second surface (upper surface) of the semiconductor layer 13, the first electrodes 31a and 31b are provided. The first electrodes 31a and 31b are spaced apart from each other, and are each provided for one of the pixels P. The first electrodes 31a and 31b are electrically connected to the selection regions 14a and 14b, respectively. The first electrodes 31a and 31b are embedded in openings through the first insulating film 21 and the second insulating film 22, and contact first surfaces (upper surfaces) of the selection regions 14a and 14b. The side surfaces of the first electrodes 31a and 31b contact the first insulating film 21 and the second insulating film 22. The thicknesses of the first electrodes 31a and 31b are larger than the total thickness of the first insulating film 21 and the second insulating film 22. The first electrodes 31a and 31b are provided such that parts (upper portions) of the first electrodes 31a and 31b protrude from a second surface (upper surface) of the second insulating film 22, the second surface being opposite to a first surface (lower surface) on the side of the first insulating film 21. For example, the first electrodes 31a and 31b have rectangular planar patterns.

For example, the first electrodes 31a and 31b include a single element which is any one of titanium (Ti), tungsten (W), titanium nitride (TiN), platinum (Pt), gold (Au), germanium (Ge), palladium (Pd), zinc (Zn), nickel (Ni), indium (In), and aluminum (Al) or an alloy including at least one type of these. The first electrodes 31a and 31b may each be a single film of any one of these materials or may be a stacked film including a combination of two or more types.

The first electrodes 31a and 31b are supplied with a voltage for reading out signal charges (holes) generated in the light absorption layer 12. For example, the first electrodes 31a and 31b are electrically connected to a pixel circuit and a silicon substrate for performing signal reading via bumps, vias, or the like. For example, various types of wire or the like are provided on the silicon substrate.

On the side of the first surface (lower surface) of the light absorption layer 12, an n⁺-type semiconductor layer 11 is provided. For example, the semiconductor layer 11 shared by the pixels P is provided. The semiconductor layer 11 contacts the light absorption layer 12. The semiconductor layer 11 functions as a contact section. The semiconductor layer 11 can include a compound semiconductor material having bandgap energy greater than that of the compound semiconductor material included in the light absorption layer 12. For example, in a case where the light absorption layer 12 includes InGaAs, InP can be used for the semiconductor layer 11. For example, as the compound semiconductor material included in the semiconductor layer 11, at least a group III-V semiconductor including any one of In, Ga, Al, As, P, Sb, and N and a group IV semiconductor including at least any one of Si, C, and Ge can be used. Specifically, other than InP, examples include InGaAsP, InAsSb, InGaP, GaAsSb and InAlAs, GaN, SiC, SiGe, and the like. For example, the thickness of the semiconductor layer 11 is approximately 200 to 5000 nm.

On a second surface (lower surface) of the semiconductor layer 11, the second surface being opposite to a first surface (upper surface) on the side of the light absorption layer 12, a second electrode 32 is provided. For example, as an electrode shared by the pixels P, the second electrode 32 is provided on the side of the first surface (lower surface) of the light absorption layer 12 via the semiconductor layer 11. The second electrode 32 discharges an electric charge which is a part of an electric charge generated in the light absorption layer 12 and which is not used as a signal charge. In the first embodiment, holes are read out as signal charges from the first electrodes 31a and 31b, and electrons are discharged from the second electrode 32.

The second electrode 32 includes a transparent electrically conductive film that can transmit the incident light L such as infrared rays, and, for example, has transmittance which is equal to or higher than 50% regarding transmission of light with a wavelength of 1.6 μm. For example, as the material of the second electrode 32, indium tin oxide (ITO) can be used. In a case where the second electrode 32 does not cover the entire second surface (lower surface) of the semiconductor layer 11, the material of the second electrode 32 is not required to be a transparent material.

Next, operation of the solid-state image pickup apparatus 1 according to the first embodiment is explained with a focus on the pixels P depicted in FIG. 4. Each pixel P is controlled by pixel transistors such as a transfer transistor, a reset transistor, an amplification transistor, and a selection transistor which are not depicted.

For example, when the light L with a wavelength in the visible region, the infrared region, or the like enters the light absorption layer 12 via the second electrode 32 and the semiconductor layer 11, the light L is absorbed in the light absorption layer 12, and pairs of holes and electrons are generated due to photoelectric conversion. At this time, for example, when a predetermined voltage is applied to the first electrodes 31a and 31b, a potential gradient is generated in the light absorption layer 12, and electric charges (holes) which is one of the generated electric charges is read out, as signal charges, from the first electrodes 31a and 31b via the selection regions 14a and 14b. The signal charges is read out, as pixel signals, from the pixel region 10A, subjected to signal processing by the circuit section 130, and output to the outside.

Next, a comparative example of the light receiving element according to the first implementation example depicted in FIG. 4 is explained. As depicted in FIG. 6, the basic configuration of a light receiving element according to the comparative example is similar to the light receiving element according to the first implementation example. However, the light receiving element according to the comparative example is different from the light receiving element according to the first embodiment in that a first insulating film 21x covering each p-n junction including the semiconductor layer 13 and one of the selection regions 14a and 14b does not have a fixed electric charge.

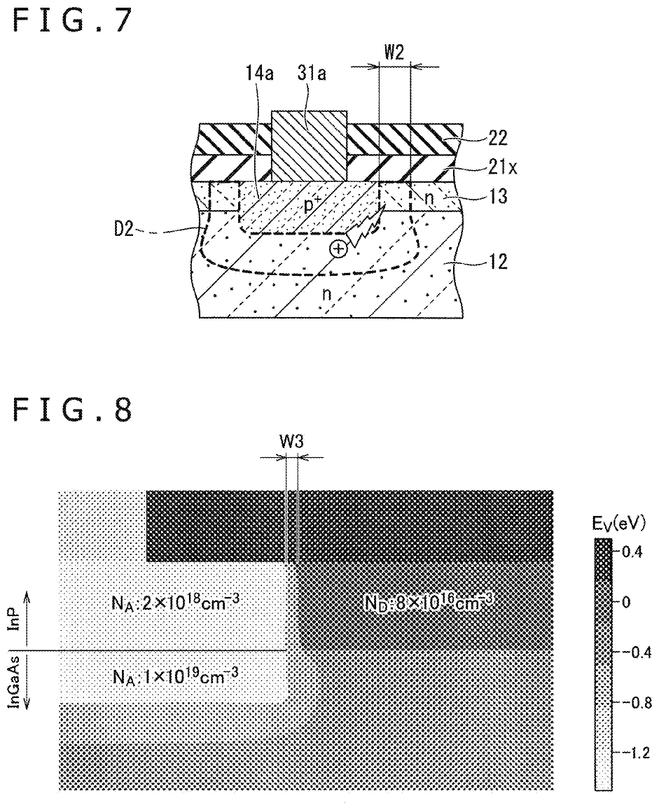

In a case where the selection regions 14a and 14b are formed by using a selective diffusion process, each p-n junction including the semiconductor layer 13 and one of the selection regions 14a and 14b contacts the interface between the semiconductor layer 13 and the first insulating film 21x. Typically, there are many defects at the interface between the semiconductor layer 13 and the first insulating film 21x, and if a p-n junction depletion layer D2 contacts the interface between the semiconductor layer 13 and the first insulating film 21x, as depicted in FIG. 7, generation of an electric charge due to the interface defect level increases. Because of this, the generated electric charge undesirably flows into the selection regions 14a and 14b as a dark current, and the noise characteristics deteriorate.

In contrast to this, according to the light receiving element according to the first embodiment, as depicted in FIG. 4 and FIG. 5, the first insulating film 21 has a fixed electric charge with the same polarity as that (those) of one(s) which is or are either the semiconductor layer 13 or the selection regions 14a and 14b included in the p-n junctions covered with the first insulating film 21 and which has or have a higher mobile charge density. The width W1 of the p-n junction depletion layer D1 can thereby be made smaller than a width W2 of the depletion layer D2 in the comparative example depicted in FIG. 7, and a dark current can be reduced.

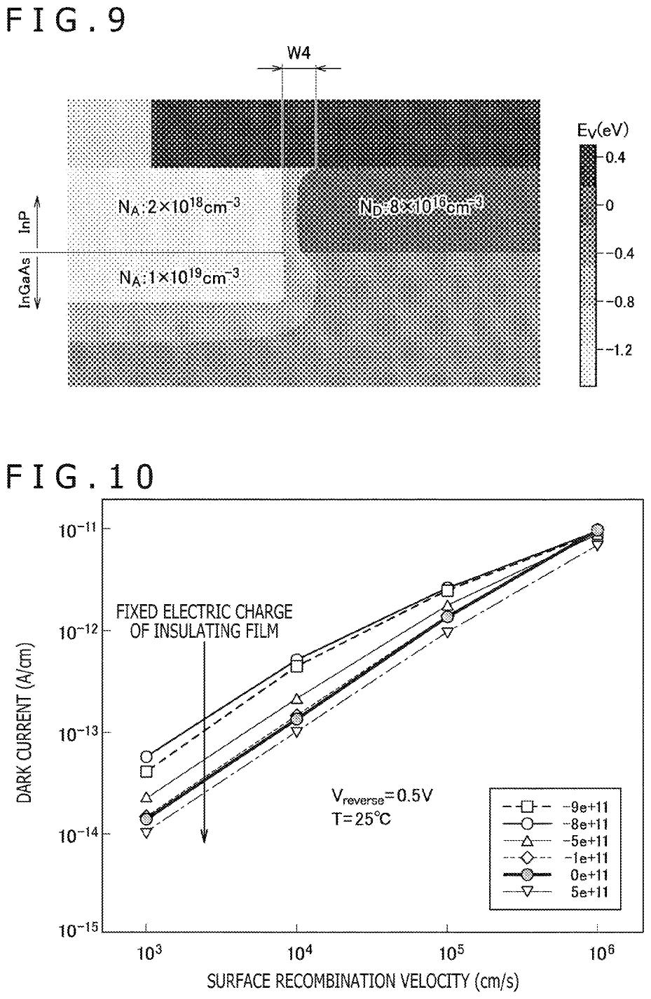

Next, device simulation results are explained with reference to FIG. 8 to FIG. 10. Device simulations were performed regarding a case, as an implementation example, where, in a structure in which a p-n junction is configured in InP on InGaAs and the p-n junction is covered with an insulating film, as depicted in FIG. 8, the acceptor density N_{A} of InGaAs is 1×10¹⁹ cm⁻³, the acceptor density N_{A} of the p-type region is 2×10¹⁸ cm⁻³, the donor density N_{D} of the n-type region is 8×10¹⁶ cm⁻³, and the insulating film has a positive fixed electric charge of +5×10¹¹ cm⁻², and regarding a case, as a comparative example, where, as depicted in FIG. 9, the structure is identical but the only difference is that the insulating film has a negative fixed electric charge of −5×10¹¹ cm⁻². As depicted in FIG. 8, in the implementation example, a width W3 of a depletion layer contacting the interface between InP and the insulating film was reduced, and a dark current decreased. On the other hand, as depicted in FIG. 9, in the comparative example, a width W4 of a depletion layer contacting the interface between InP and the insulating film widened, and a dark current increased.

FIG. 10 depicts results of computation of a dark current that are obtained by changing the polarity of an electric charge on a p-n junction in a case where, in a structure identical to the ones in FIG. 8 and FIG. 9, the acceptor density N_{A} of the p-type region is higher than the donor density N_{D} of the n-type region. It can be known from FIG. 10 that the larger the fixed electric charge is in the positive direction, the smaller the dark current is. In a case where the fixed electric charge is +5×10¹¹ cm⁻², the dark current decreased by 30% as compared with the case where there is not any fixed electric charge. On the other hand, in a case where the fixed electric charge is −5×10¹¹ cm⁻², the dark current increased by 200% as compared with the case where there is not any fixed electric charge.

<Light Receiving Element Manufacturing Method>

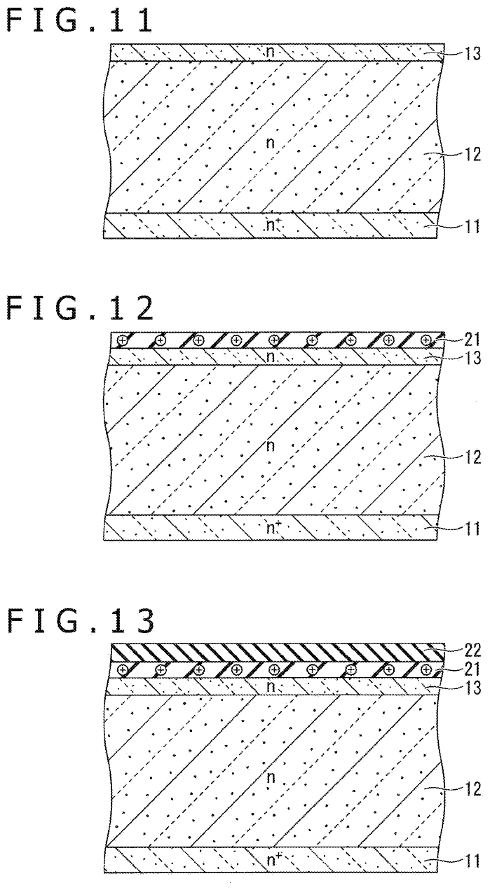

Next, a method of manufacturing the light receiving element according to the first embodiment is explained with reference to FIG. 11 to FIG. 18. Here, an explanation is given with a focus on the cross-section of the two pixels P depicted in FIG. 4.

First, as depicted in FIG. 11, the n-type light absorption layer 12, and the n-type semiconductor layer 13 are epitaxially grown sequentially on the n⁺-type semiconductor layer (semiconductor substrate) 11. Materials included in the semiconductor layer 11, the light absorption layer 12, and the semiconductor layer 13 may be compound semiconductors including at least any one of In, Ga, Al, As, P, Sb, N, Si, C, and Ge. Specifically, for example, the materials of the semiconductor layer 11, the light absorption layer 12, and the semiconductor layer 13 may be InGaAsP, InGaP, InAsSb, GaAsSb, InAlAs, SiC, SiGe, or the like. It is supposed here that the semiconductor layer 11 includes an InP substrate, the light absorption layer 12 includes InGaAs, and the semiconductor layer 13 includes InP.

Next, as depicted in FIG. 12, by a chemical vapor deposition (CVD) method, an atomic layer deposition (ALD) method, or the like, the first insulating film 21 including a SiO₂ film is formed on the semiconductor layer 13. As mentioned later, because the acceptor density N_{A} of the p-type selection regions 14a and 14b forming the p-n junctions is higher than the donor density N_{D} of the n-type semiconductor layer 13, the first insulating film 21 has positive fixed electric charges (holes) with the same polarity as those of the selection regions 14a and 14b.

Next, as depicted in FIG. 13, by a CVD method, an ALD method, or the like, the second insulating film 22 including a Si₃N₄ film or the like is deposited on the first insulating film 21. The first insulating film 21 and the second insulating film 22 function as masks in a selective diffusion process mentioned later. Because of this, in order to prevent transmission of an element to be selectively diffused, the total film thickness of the first insulating film and the second insulating film is preferably equal to or larger than 10 nm. Note that in a case where there is no second insulating film 22, the film thickness of the first insulating film 21 is preferably equal to or larger than 10 nm. In addition, in a case where one or more insulating films are stacked further on the second insulating film 22, the total film thickness of the stacked films is preferably equal to or larger than 10 nm.

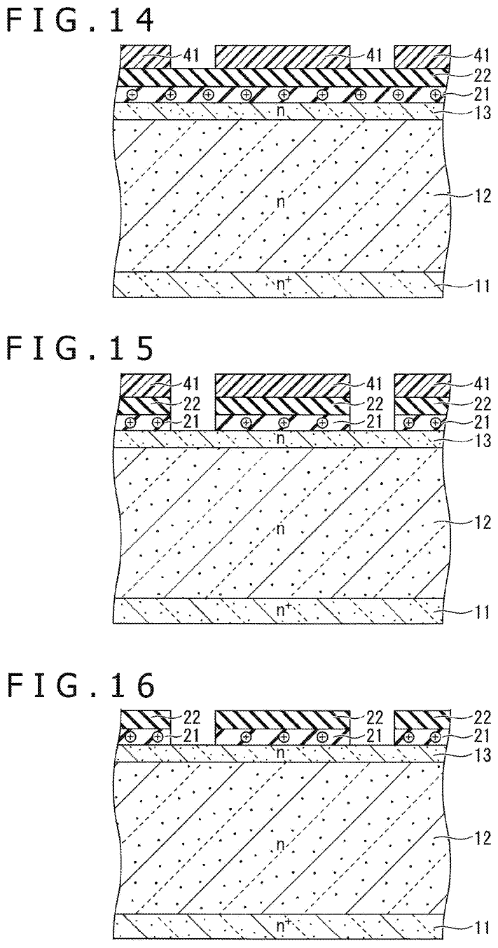

Next, the second insulating film 22 is coated with a photoresist film 41, and, as depicted in FIG. 14, patterning of the photoresist film 41 is performed by using a photolithography technology. By using, as an etching mask, the photoresist film 41 having been subjected to the patterning, parts of the first insulating film 21 and the second insulating film 22 are removed selectively by dry etching or wet etching. As a result, as depicted in FIG. 15, an opening (window) through which the upper surface of a part of the semiconductor layer 13 is exposed for each pixel P is formed through the first insulating film 21 and the second insulating film 22. Next, the photoresist film 41 is removed as depicted in FIG. 16 by dry asking or wet etching.

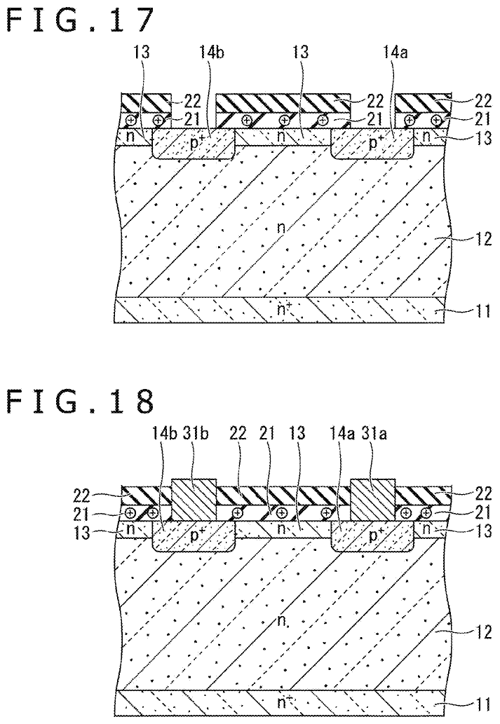

Next, as depicted in FIG. 17, by a selective diffusion process such as gas phase diffusion or solid phase diffusion, and by using the first insulating film 21 and the second insulating film 22 as masks, p-type impurities such as Zn are diffused from the upper surface of the semiconductor layer 13 via the openings through the first insulating film 21 and the second insulating film 22, and the p⁺-type selection regions 14a and 14b are formed. At this time, by a thermal treatment (annealing) approximately at 300° C. to 800° C., the selection regions 14a and 14b can be formed in such a manner as to reach the light absorption layer 12. As the impurities with which the selection regions 14a and 14b are doped, an element that functions as a dopant in a compound semiconductor can be used, and, for example, the impurities may be Zn, Mg, Cd, Be, Si, Ge, C, Sn, Pb, S, Te, P, B, As, In, Sb, Ga, As, Al, or the like.

Next, by a sputtering method, a vapor deposition method, or the like, a metal film is deposited in such a manner as to fill the openings through the first insulating film 21 and the second insulating film 22. Then, by performing patterning of the metal film by a photolithography technology and etching, as depicted in FIG. 18, each of the first electrodes 31a and 31b is formed for one of the pixels P on the selection regions 14a and 14b. In addition, as depicted in FIG. 4, by a sputtering method, a vapor deposition method, or the like, the second electrode 32 shared by the pixels P is formed on the lower surface of the semiconductor layer 11. As a result, the light receiving element according to the first embodiment is completed.

### Second Embodiment

<Configuration of Light Receiving Element>

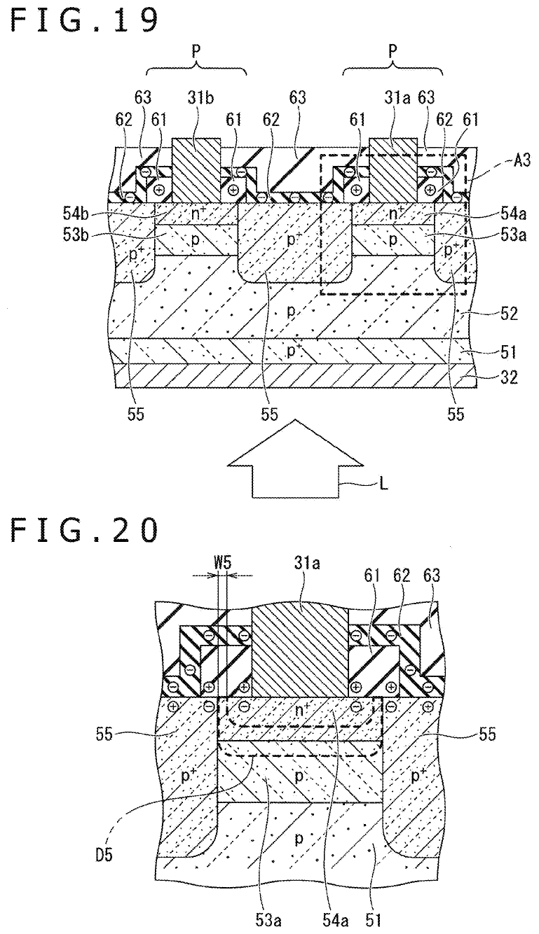

As depicted in FIG. 19, a light receiving element according to a second embodiment is different from the configuration in the first embodiment depicted in FIG. 4 in that a selection region 55 is provided between the pixels P. As depicted in FIG. 19, the light receiving element according to the second embodiment includes a p-type light absorption layer (photoelectric conversion layer) 52, p-type semiconductor layers 53a and 53b provided on a second surface (upper surface) of the light absorption layer 52, the second surface being opposite to a first surface (lower surface) from which the light L enters, and n⁺-type semiconductor layers 54a and 54b provided on second surfaces (upper surfaces) of the semiconductor layers 53a and 53b, the second surfaces being opposite to first surfaces (lower surfaces) on the side of the light absorption layer 52.

The light absorption layer 52 shared by the plurality of pixels P is provided. The light absorption layer 52 absorbs light with a predetermined wavelength such as a wavelength in a region from the visible region to the short-wavelength infrared region or the like, and generates a signal charge by photoelectric conversion. The light absorption layer 52 includes a compound semiconductor material. Because the compound semiconductor material included in the light absorption layer 52 is similar to that of the light absorption layer 12 of the light receiving element according to the first embodiment, an overlapping explanation is omitted.

The semiconductor layers 53a and 53b can include a compound semiconductor material having bandgap energy greater than that of the compound semiconductor material included in the light absorption layer 52. For example, in a case where the light absorption layer 52 includes InGaAs, InP can be used for the semiconductor layers 53a and 53b. Because the compound semiconductor material included in the semiconductor layers 53a and 53b is similar to that of the semiconductor layer 13 of the light receiving element according to the first embodiment, an overlapping explanation is omitted. Note that the p-type semiconductor layers 53a and 53b may not be included in the configuration, and, in that case, the light absorption layer 52 may contact the semiconductor layers 54a and 54b.

The semiconductor layers 54a and 54b function as contact sections. The semiconductor layers 54a and 54b can include a compound semiconductor material having bandgap energy greater than that of the compound semiconductor material included in the light absorption layer 52. The semiconductor layers 54a and 54b may include the same material as that of the semiconductor layers 53a and 53b or may include a different material. For example, in a case where the light absorption layer 52 includes InGaAs, InP can be used for the semiconductor layers 54a and 54b. Because the compound semiconductor material included in the semiconductor layers 54a and 54b is similar to that of the semiconductor layer 13 of the light receiving element according to the first embodiment, an overlapping explanation is omitted.

The p⁺-type selection region 55 is provided in such a manner as to reach the light absorption layer 52 from second surfaces (upper surfaces) of the semiconductor layers 54a and 54b, the second surfaces being opposite to first surfaces (lower surfaces) on the side of the light absorption layer 52. The selection region 55 may penetrate the light absorption layer 52 and reach a semiconductor layer 51. For example, the selection region 55 includes a diffusion region in which p-type impurities such as zinc (Zn) are diffused by a selective diffusion process. Because the configuration of the selection region 55 is similar to that of the selection regions 14a and 14b of the light receiving element according to the first embodiment, an overlapping explanation is omitted.

In the second embodiment, a selection region 55 is provided spaced apart from the first electrodes 31a and 31b each corresponding to one of the pixels P, and between the first electrodes 31a and 31b. The semiconductor layers 54a and 54b of the adjacent pixels P are electrically separated by the selection region 55. Therefore, signal reading of each pixel P can be realized. The selection region 55 has a grid-like planar pattern such that the selection region 55 functions as a partition between the pixels P. The selection region 55 contacts the semiconductor layers 54a and 54b, the semiconductor layers 53a and 53b, and the light absorption layer 52. The selection region 55 is included in a p-n junction along with each of the semiconductor layers 54a and 54b.

On the side of the second surface (upper surface) of the semiconductor layers 54a and 54b, a first insulating film 61 is provided in such a manner as to contact the semiconductor layers 54a and 54b and the selection region 55. The first insulating film 61 covers a p-n junction formed by the selection region 55 and each of the semiconductor layers 54a and 54b. The first insulating film 61 has a frame-like planar pattern such that the first insulating film 61 surrounds the side surfaces of the first electrodes 31a and 31b each of which corresponds to one of the pixels P. Because the material of the first insulating film 61 is similar to that of the first insulating film 21 of the light receiving element according to the first embodiment, an overlapping explanation is omitted.

The first insulating film 61 has a fixed electric charge with the same polarity as that (those) of one(s) which is or are either the semiconductor layers 54a and 54b or the selection region 55 included in the p-n junctions covered with the first insulating film 61 and which has or have a higher mobile charge density. In the case explained in the second embodiment, the acceptor density N_{A} of the p⁺-type selection region 55 forming the p-n junctions is higher than the donor density N_{D} of the n-type semiconductor layers 54a and 54b (N_{A} > N_{D}). In this case, as depicted in FIG. 20, the first insulating film 61 has positive fixed electric charges (holes) with the same polarity as that of the selection region 55. Electrons are thereby induced near the interfaces of the n-type semiconductor layers 54a and 54b facing the first insulating film 61, and a width W5 of a p-n junction depletion layer D5 is reduced. Therefore, a dark current generated in the depletion layer D5 can be reduced.

On the other hand, although not depicted, in a case where the acceptor density N_{A} of the p-type selection region 55 forming the p-n junctions is lower than the donor density N_{D} of the n-type semiconductor layers 54a and 54b (in a case where N_{A}<N_{D}), the first insulating film 61 has negative fixed electric charges (electrons) with the same polarity as those of the semiconductor layers 54a and 54b. Holes are thereby induced near the interfaces of the n-type semiconductor layers 54a and 54b facing the first insulating film 61, and the width W5 of the p-n junction depletion layer D5 is reduced. Therefore, a dark current generated in the depletion layer D5 can be reduced.

As depicted in FIG. 19, a second insulating film 62 is provided on a second surface (upper surface) of the first insulating film 61, the second surface being opposite to a first surface (lower surface) on the side of the semiconductor layer 54a and 54b. The second insulating film 62 contacts the selection region 55 at portions where the first insulating film 61 is not formed between the adjacent pixels P. Because the material of the second insulating film 62 is similar to that of the second insulating film 22 of the light receiving element according to the first embodiment, an overlapping explanation is omitted.

In a case where the selection region 55 is provided between the pixels P and the charge density of the selection region 55 is higher than the charge density of the semiconductor layers 54a and 54b, the second insulating film 62 preferably has a fixed electric charge with a reverse polarity of the polarity of the selection region 55 and the first insulating film 61. For example, as depicted in FIG. 19 and FIG. 20, in a case where the selection region 55 has a p-type polarity, the second insulating film 62 preferably has negative fixed electric charges (electrons). Holes are thereby induced at the interface of the selection region 55 facing the second insulating film 62, and a dark current generated at the interface between the selection region 55 and the second insulating film 62 can be reduced. Note that the second insulating film 62 may have a positive fixed electric charge or may not have a fixed electric charge.

In addition, although not depicted, in a case where the entire polarities are reverse polarities and the selection region 55 has an n-type polarity, the second insulating film 62 preferably has positive fixed electric charges (holes). Electrons are thereby induced at the interface of the selection region 55 facing the second insulating film 62, and a dark current generated at the interface between the selection region 55 and the second insulating film 62 can be reduced. Note that in a case where the charge density of the selection region 55 is lower than the charge density of the semiconductor layers 54a and 54b, the second insulating film 62 preferably has a fixed electric charge with the same polarity as that of the first insulating film 61.

On a second surface (upper surface) of the second insulating film 62, the second surface being opposite to a first surface (lower surface) on the side of the first insulating film 61, a third insulating film 63 is provided. As a material of the third insulating film 63, a material similar to the materials of the first insulating film 61 and the second insulating film 62 can be used. The third insulating film 63 may have a positive or negative fixed electric charge or may not have a fixed electric charge.

On the side of the second surface (upper surface) of the side on the semiconductor layers 54a and 54b, the first electrodes 31a and 31b are provided. The first electrodes 31a and 31b are electrically connected to the semiconductor layers 54a and 54b. The first electrodes 31a and 31b are supplied with a voltage for reading out signal charges (electrons) generated in the light absorption layer 52.

On the side of the first surface (lower surface) of the light absorption layer 52, the p⁺-type semiconductor layer 51 is provided. For example, the semiconductor layer 51 shared by the pixels P is provided. Because the material of the semiconductor layer 51 is similar to that of the semiconductor layer 11 of the light receiving element according to the first embodiment, an overlapping explanation is omitted.

On a second surface (lower surface) of the semiconductor layer 51, the second surface being opposite to a first surface (upper surface) on the side of the light absorption layer 52, the second electrode 32 is provided. The second electrode 32 discharges electric charges (holes) which are a part of electric charges generated in the light absorption layer 52 and which are not used as signal charges.

According to the light receiving element according to the second embodiment, as depicted in FIG. 19 and FIG. 20, the first insulating film 61 has a fixed electric charge with the same polarity as that (those) of one(s) which is or are either the semiconductor layers 54a and 54b or the selection region 55 included in the p-n junctions covered with the first insulating film 61 and which has or have a higher mobile charge density. The width W5 of the p-n junction depletion layer D5 can thereby be reduced, and a dark current that is easily generated in the depletion layer D5 can be reduced.

<Light Receiving Element Manufacturing Method>

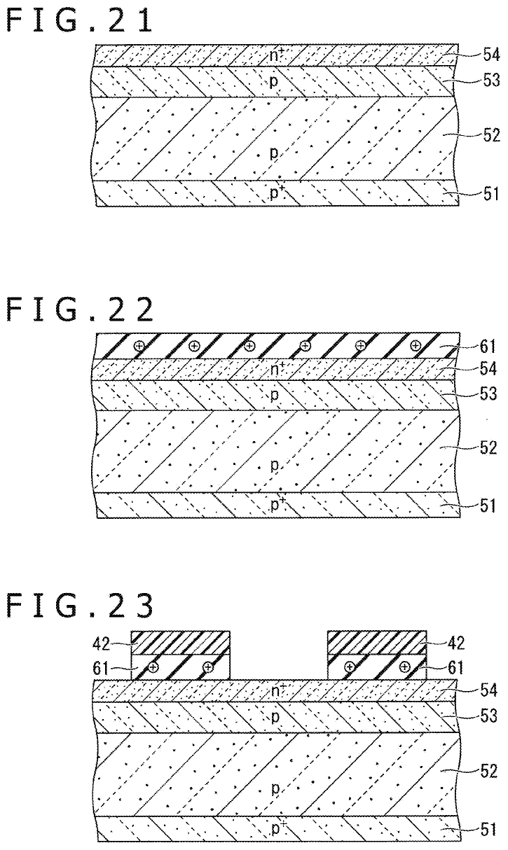

Next, a method of manufacturing the light receiving element according to the second embodiment is explained with reference to FIG. 21 to FIG. 27. Here, an explanation is given with a focus on the two pixels P depicted in FIG. 19.

First, as depicted in FIG. 21, the p-type light absorption layer 52, a p-type semiconductor layer 53, and an n⁺-type semiconductor layer 54 are epitaxially grown sequentially on the p⁺-type semiconductor layer (semiconductor substrate) 51. Next, as depicted in FIG. 22, by a CVD method, an ALD method, or the like, the first insulating film 61 having a positive fixed electric charge is deposited on the semiconductor layer 54.

Next, the first insulating film 61 is coated with a photoresist film 42, and patterning of the photoresist film 42 is performed by using a photolithography technology. By using, as an etching mask, the photoresist film 42 having been subjected to the patterning, as depicted in FIG. 23, a part of the first insulating film 61 is removed selectively by dry etching or the like. Thereafter, the photoresist film 42 is removed.

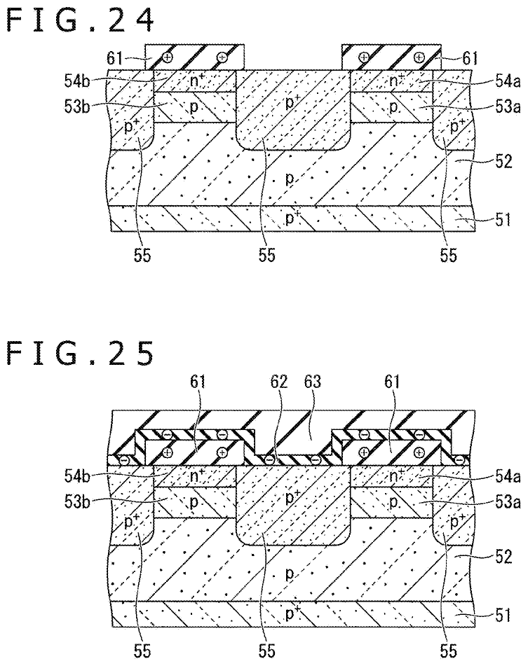

Next, as depicted in FIG. 24, by using the first insulating film 61 as a mask, p-type impurities such as Zn are diffused by a selective diffusion process such as solid phase diffusion or gas phase diffusion. The p⁺-type selection region 55 is thereby formed in such a manner as to reach the light absorption layer 52 from the upper surface of the semiconductor layer 54. The selection region 55 functions as a partition between the semiconductor layers 53a and 53b and between the semiconductor layers 54a and 54b, the partition functioning as a partition between the pixels P.

Next, as depicted in FIG. 25, by a CVD method, an ALD method, or the like, on the upper surfaces of the first insulating film 61 and the selection region 55, the second insulating film 62 and the third insulating film 63 are deposited sequentially. Note that, as depicted in FIG. 25, for example, the second insulating film 62 has a negative fixed electric charge but may have a positive fixed electric charge or may not have a fixed electric charge. In addition, the third insulating film 63 may have a positive or negative fixed electric charge or may not have a fixed electric charge.

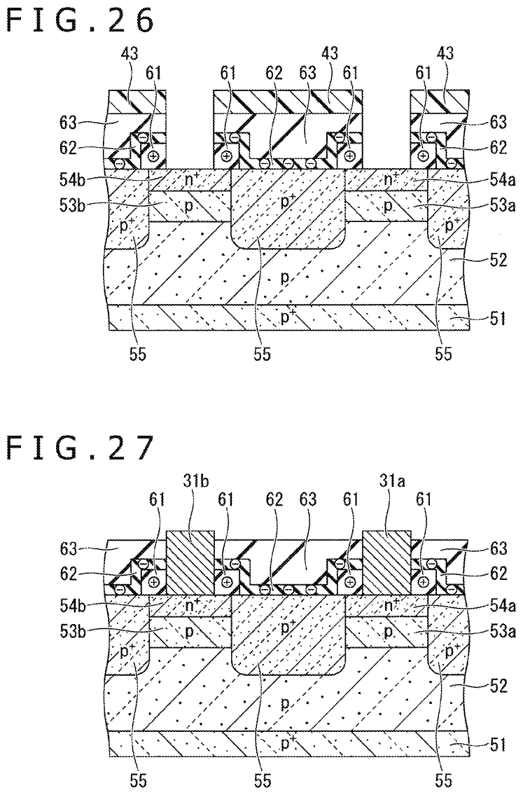

Next, the third insulating film 63 is coated with a photoresist film 43, and patterning of the photoresist film 43 is performed by using a photolithography technology. By using, as an etching mask, the photoresist film 43 having been subjected to the patterning, parts of the third insulating film 63, the second insulating film 62, and the first insulating film 61 are removed selectively by dry etching or the like. As a result, as depicted in FIG. 26, an opening penetrating the third insulating film 63, the second insulating film 62, and the first insulating film 61 is formed for each of the pixels P.

Next, by a sputtering method, a vapor deposition method, or the like, a metal film is deposited in such a manner as to fill the openings through the third insulating film 63, the second insulating film 62, and the first insulating film 61. Then, patterning of the metal film is performed by using a photolithography technology and an etching technology. As a result, as depicted in FIG. 27, the first electrodes 31a and 31b are formed on the semiconductor layers 54a and 54b. Thereafter, as depicted in FIG. 19, the second electrode 32 is formed, and the light receiving element according to the third embodiment is thereby completed.

### Third Embodiment

<Configuration of Light Receiving Element>

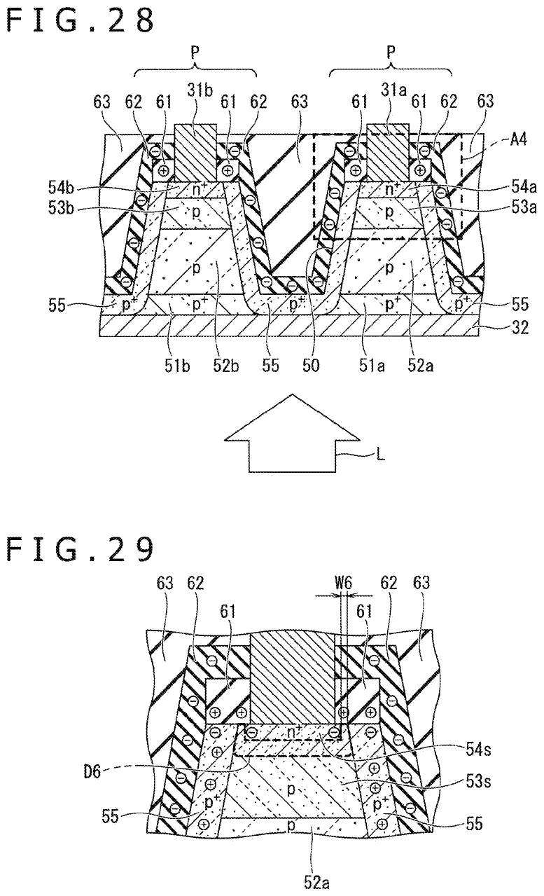

As depicted in FIG. 28, a light receiving element according to a third embodiment has the same configuration as that in the second embodiment depicted in FIG. 19 in that the selection region 55 is provided between the pixels P. However, the light receiving element according to the third embodiment has a configuration different from that in the second embodiment in that a groove (trench) 50 is provided between the pixels P.

As depicted in FIG. 28, the light receiving element according to the third embodiment includes p-type light absorption layers (photoelectric conversion layers) 52a and 52b, the p-type semiconductor layers 53a and 53b provided on second surfaces (upper surfaces) of the light absorption layers 52a and 52b, the second surfaces being opposite to first surfaces (lower surfaces) from which the light L enters, and the n⁺-type semiconductor layers 54a and 54b provided on second surfaces (upper surfaces) of the semiconductor layers 53a and 53b, the second surfaces being opposite to first surfaces (lower surfaces) on the side of the light absorption layer 52a and 52b.

Each of the light absorption layers 52a and 52b is provided for one of the pixels P. The light absorption layers 52a and 52b absorb light with a predetermined wavelength such as a wavelength in a region from the visible region to the short-wavelength infrared region or the like, and generates a signal charge by photoelectric conversion. The light absorption layers 52a and 52b include a compound semiconductor material. Because the compound semiconductor material included in the light absorption layers 52a and 52b is similar to that of the light absorption layer 52 of the light receiving element according to the second embodiment, an overlapping explanation is omitted.

The semiconductor layers 53a and 53b can include a compound semiconductor material having bandgap energy greater that of than the compound semiconductor material included in the light absorption layers 52a and 52b. For example, in a case where the light absorption layers 52a and 52b include InGaAs, InP can be used for the semiconductor layers 53a and 53b. Note that the p-type semiconductor layers 53a and 53 may not be included in the configuration, and, in that case, the light absorption layers 52a and 52b may contact the semiconductor layers 54a and 54b.

The semiconductor layers 54a and 54b function as contact sections. The semiconductor layers 54a and 54b can include a compound semiconductor material having bandgap energy greater than that of the compound semiconductor material included in the light absorption layers 52a and 52b. The semiconductor layers 54a and 54b may include the same material as that of the semiconductor layers 53a and 53b or may include a different material. For example, in a case where the light absorption layers 52a and 52b include InGaAs, InP can be used for the semiconductor layers 54a and 54b.

The trench 50 is provided in such a manner as to penetrate the semiconductor layers 54a and 54b, the semiconductor layers 53a and 53b and the light absorption layers 52a and 52b. Note that the trench 50 may not penetrate the light absorption layers 52a and 52b but may reach parts of the light absorption layers 52a and 52b in the depth direction. The trench 50 has a grid-like planar pattern such that the trench 50 functions as a partition between the pixels P.

The p⁺-type selection region 55 is provided along the trench 50. For example, the selection region 55 includes a diffusion region in which p-type impurities such as zinc (Zn) are diffused by a selective diffusion process. The selection region 55 is provided in such a manner as to contact the semiconductor layers 54a and 54b, the semiconductor layers 53a and 53b, the light absorption layers 52a and 52b, and semiconductor layers 51a and 51b. The selection region 55 contacts the second electrode 32 in FIG. 28 but is not required to contact the second electrode 32. The p⁺-type selection region 55 is included in p-n junctions along with the n⁺-type semiconductor layers 54a and 54b.

On the side of the second surface (upper surface) of the semiconductor layers 54a and 54b, a first insulating film 61 is provided in such a manner as to contact the semiconductor layers 54a and 54b and the selection region 55. The first insulating film 61 covers a p-n junction formed by the selection region 55 and each of the semiconductor layers 54a and 54b. Because the material of the first insulating film 61 is similar to that of the first insulating film 21 of the light receiving element according to the first embodiment, an overlapping explanation is omitted.

The first insulating film 61 has a fixed electric charge with the same polarity as that (those) of one(s) which is or are either the semiconductor layers 54a and 54b or the selection region 55 included in the p-n junctions covered with the first insulating film 61 and which has or have a higher mobile charge density. In the case explained in the third embodiment, the acceptor density N_{A} of the p⁺-type selection region 55 forming the p-n junctions is higher than the donor density N_{D} of the n-type semiconductor layers 54a and 54b (N_{A} > N_{D}). In this case, as depicted in FIG. 29, the first insulating film 61 has positive fixed electric charges (holes) with the same polarity as that of the selection region 55. Electrons are thereby induced near the interfaces of the n-type semiconductor layers 54a and 54b facing the first insulating film 61, and a width W6 of a p-n junction depletion layer D6 is reduced. Therefore, a dark current generated in the depletion layer D6 can be reduced.

On the other hand, although not depicted, in a case where the acceptor density N_{A} of the p-type selection region 55 forming the p-n junctions is lower than the donor density N_{D} of the n-type semiconductor layers 54a and 54b (in a case where N_{A}<N_{D}), the first insulating film 61 has negative fixed electric charges (electrons) with the same polarity as those of the semiconductor layers 54a and 54b. Holes are thereby induced near the interfaces of the n-type semiconductor layers 54a and 54b facing the first insulating film 61, and the width W6 of the p-n junction depletion layer D6 is reduced. Therefore, a dark current generated in the depletion layer D6 can be reduced.

As depicted in FIG. 28, the second insulating film 62 is provided on the second surface (upper surface) of the first insulating film 61, the second surface being opposite to the first surface (lower surface) on side of the semiconductor layer 54a and 54b. The second insulating film 62 is provided along the trench 50. The second insulating film 62 contacts the selection region 55. Because the material of the second insulating film 62 is similar to that of the second insulating film 22 of the light receiving element according to the first embodiment, an overlapping explanation is omitted.

Here, the second insulating film 62 preferably has a fixed electric charge with the reverse polarity of the polarity of the selection region 55. For example, as depicted in FIG. 28 and FIG. 29, in a case where the selection region 55 has a p-type polarity, the second insulating film 62 preferably has negative fixed electric charges (electrons). Holes are thereby induced at the interface of the selection region 55 facing the second insulating film 62, and a dark current generated at the interface between the selection region 55 and the second insulating film 62 can be reduced. Note that the second insulating film 62 may have a positive fixed electric charge or may not have a fixed electric charge.

Note that, although not depicted, in a case where the selection region 55 has an n-type polarity, the second insulating film 62 preferably has positive fixed electric charges (holes). Electrons are thereby induced at the interface of the selection region 55 facing the second insulating film 62, and a dark current generated at the interface between the selection region 55 and the second insulating film 62 can be reduced.

On the second surface (upper surface) of the second insulating film 62, the second surface being opposite to the first surface (lower surface) on the side of the first insulating film 61, the third insulating film 63 is provided. The third insulating film 63 is provided in such a manner to fill the trench 50 via the second insulating film 62. As a material of the third insulating film 63, a material similar to the materials of the first insulating film 61 and the second insulating film 62 can be used. The third insulating film 63 may have a positive or negative fixed electric charge or may not have a fixed electric charge.

On the side of the second surface (upper surface) of each of the semiconductor layers 54a and 54b, the first electrodes 31a and 31b are provided. The first electrodes 31a and 31b are electrically connected to the semiconductor layers 54a and 54b. The first electrodes 31a and 31b are supplied with a voltage for reading out signal charges (electrons) generated in the light absorption layers 52a and 52b.

On the side of the first surface (lower surface) of each of the light absorption layers 52a and 52b, the p⁺-type semiconductor layers 51a and 51b are provided. For example, the semiconductor layers 51a and 51b are partitioned by the trench 50 and the selection region 55, and each of the semiconductor layers 51a and 51b is provided for one of the pixels P. Because the material of the semiconductor layers 51a and 51b is similar to that of the semiconductor layer 51 of the light receiving element according to the second embodiment, an overlapping explanation is omitted.

On second surfaces (lower surfaces) of the semiconductor layers 51a and 51b, the second surfaces being opposite to first surfaces (upper surfaces) on the side of the light absorption layer 52a and 52b, the second electrode 32 shared by the pixels P is provided. The second electrode 32 discharges electric charges (holes) which is a part of electric charges generated in the light absorption layers 52a and 52b and which is not used as a signal charge.

According to the light receiving element according to the third embodiment, as depicted in FIG. 28 and FIG. 29, the first insulating film 61 has a fixed electric charge with the same polarity as that (those) of one(s) which is or are either the semiconductor layers 54a and 54b or the selection region 55 included in the p-n junctions covered with the first insulating film 61 and which has or have a higher mobile charge density. The width W6 of the p-n junction depletion layer D6 can thereby be reduced, and a dark current that is easily generated in the depletion layer D6 can be reduced.

<Light Receiving Element Manufacturing Method>

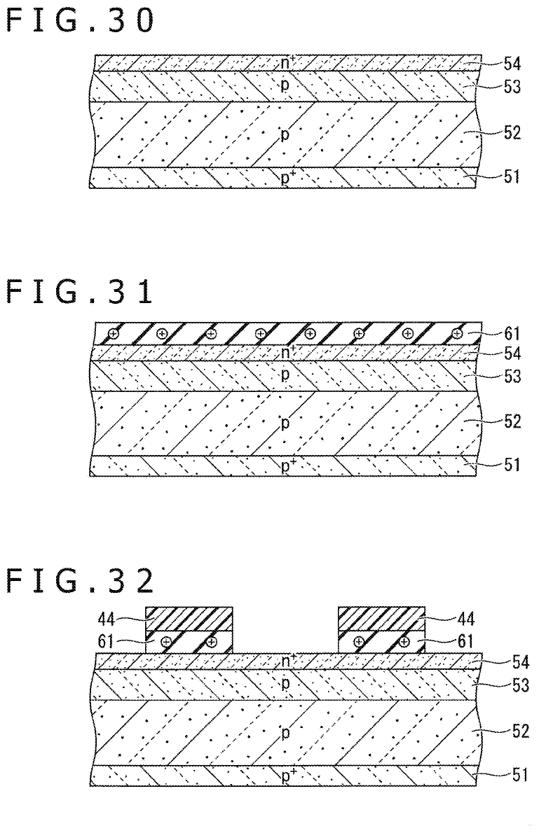

Next, a method of manufacturing the light receiving element according to the third embodiment is explained with reference to FIG. 30 to FIG. 37. Here, an explanation is given with a focus on the cross-section of the two pixels P depicted in FIG. 28.

First, as depicted in FIG. 30, the p-type light absorption layer 52, the p-type semiconductor layer 53, and the n⁺-type semiconductor layer 54 are epitaxially grown sequentially on the p⁺-type semiconductor layer (semiconductor substrate) 51. Next, as depicted in FIG. 31, by a CVD method, an ALD method, or the like, the first insulating film 61 having a positive fixed electric charge is deposited on the semiconductor layer 54.

Next, the first insulating film 61 is coated with a photoresist film 44, and patterning of the photoresist film 44 is performed by using a photolithography technology. By using, as an etching mask, the photoresist film 44 having been subjected to the patterning, as depicted in FIG. 32, a part of the first insulating film 61 is removed selectively by dry etching or the like. Thereafter, the photoresist film 44 is removed.

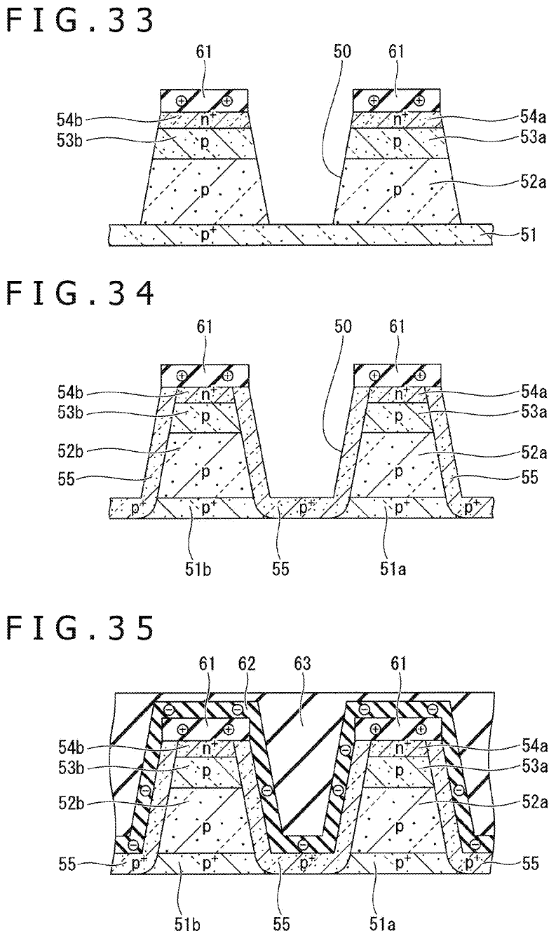

Next, by using the first insulating film 61 as an etching mask, the semiconductor layer 54, the semiconductor layer 53, and the light absorption layer 52 are removed selectively by dry etching or the like, and the trench 50 is thereby formed. As a result, as depicted in FIG. 33, the trench 50 functions as a partition between the semiconductor layers 54a and 54b, between the semiconductor layers 53a and 53b, and between the light absorption layers 52a and 52b, the partition functioning as a partition between the pixels P.

Next, as depicted in FIG. 34, by using the first insulating film 61 as a mask, the p⁺-type selection region 55 is formed along the trench 50 by a selective diffusion process. As a result, the selection region 55 functions as a partition between the semiconductor layers 51a and 51b, the partition functioning as a partition between the pixels P.

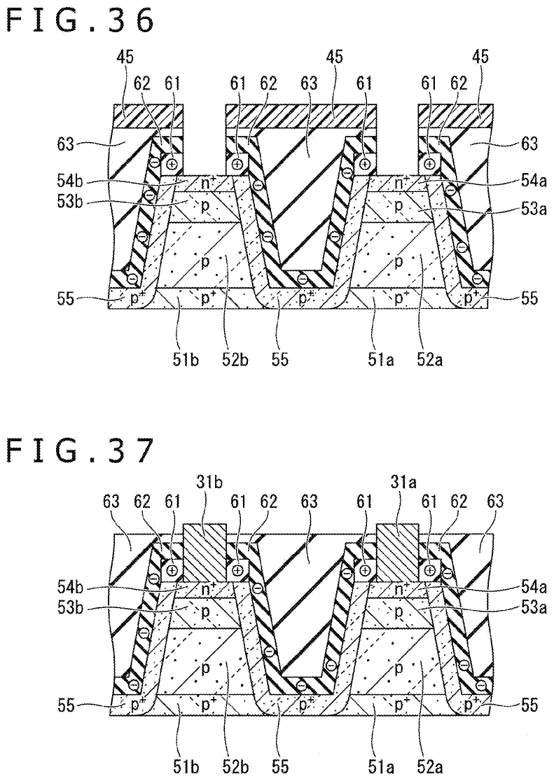

Next, as depicted in FIG. 35, by a CVD method, an ALD method, or the like, the second insulating film 62 and the third insulating film 63 are deposited sequentially in such a manner as to fill the trench 50. Note that, as depicted in FIG. 35, for example, the second insulating film 62 has a negative fixed electric charge but may have a positive fixed electric charge or may not have a fixed electric charge. In addition, the third insulating film 63 may have a positive or negative fixed electric charge or may not have a fixed electric charge.

Next, the third insulating film 63 is coated with a photoresist film 45, and patterning of the photoresist film 45 is performed by using a photolithography technology. By using, as an etching mask, the photoresist film 45 having been subjected to the patterning, as depicted in FIG. 36, parts of the third insulating film 63, the second insulating film 62, and the first insulating film 61 are removed selectively by dry etching or the like. An opening penetrating the third insulating film 63, the second insulating film 62, and the first insulating film 61 is formed for each of the pixels P.

Next, by a sputtering method, a vapor deposition method, or the like, a metal film is deposited in such a manner as to fill the openings through the third insulating film 63, the second insulating film 62 and the first insulating film 61. Then, patterning of the metal film is performed by a photolithography technology and an etching technology. As a result, as depicted in FIG. 37, the first electrodes 31a and 31b are formed on the semiconductor layers 54a and 54b. Thereafter, as depicted in FIG. 28, the second electrode 32 is formed by a sputtering method, a vapor deposition method, or the like, and the light receiving element according to the third embodiment is thereby completed.

### Fourth Embodiment

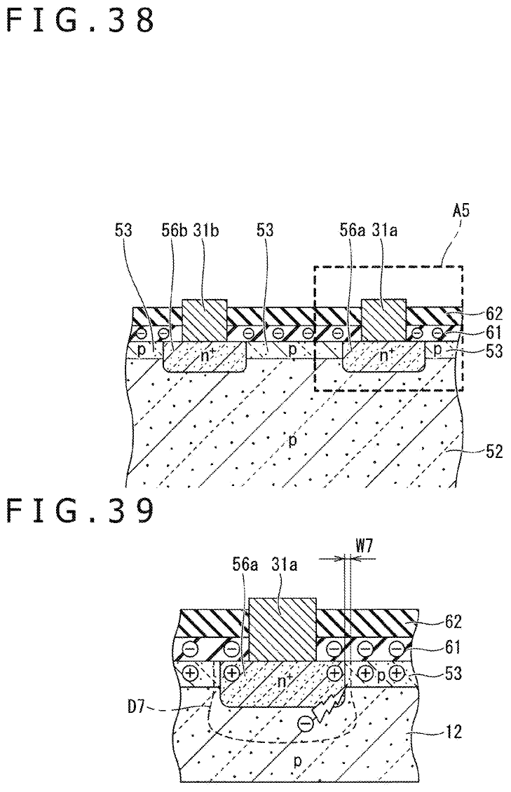

As depicted in FIG. 38, a light receiving element according to a fourth embodiment has reverse polarities of the polarities of the light receiving element according to the first embodiment depicted in FIG. 4. That is, the light receiving element according to the fourth embodiment includes a p-type light absorption layer (photoelectric conversion layer) 52, a p-type semiconductor layer 53 provided on a second surface (upper surface) of the light absorption layer 52, the second surface being opposite to a first surface (lower surface) from which light L enters, and n⁺-type selection regions 56a and 56b provided in such a manner as to reach the light absorption layer 52 from a second surface (upper surface) of the semiconductor layer 53, the second surface being opposite to a first surface (lower surface) on the side of the light absorption layer 52.

The selection regions 56a and 56b contact the first electrodes 31a and 31b and function as contact sections. The selection regions 56a and 56b include diffusion layers in which germanium (Ge) is diffused as n-type impurities, for example. On the first surface of the light absorption layer 52, the p⁺-type semiconductor layer 51 is provided. In the fourth embodiment, electrons are read out, as a signal charge, from the first electrodes 31a and 31b, and holes are discharged from the second electrode 32.

The first insulating film 61 has a fixed electric charge with the same polarity as that (those) of one(s) which is or are either the semiconductor layer 53 or the selection regions 56a and 56b included in the p-n junctions covered with the first insulating film 61 and which has or have a higher mobile charge density. In the case explained in the fourth embodiment, the acceptor density N_{A} of the p-type semiconductor layer 53 forming the p-n junctions is lower than the donor density N_{D} of the n-type selection regions 56a and 56b (N_{A}<N_{D}). In this case, as depicted in FIG. 39, the first insulating film 61 has negative fixed electric charges (electrons) with the same polarity as those of the n-type selection regions 56a and 56b. Holes are thereby induced near the interface of the p-type semiconductor layer 53 facing the first insulating film 61, and a width W7 of a p-n junction depletion layer D7 is reduced. Therefore, a dark current generated in the depletion layer D7 can be reduced.

On the other hand, although not depicted, in a case where the acceptor density N_{A} of the p-type semiconductor layer 53 forming the p-n junctions is higher than the donor density N_{D} of the n-type selection regions 56a and 56b (in a case where N_{A} > N_{D}), the first insulating film 21 has positive fixed electric charges (holes) with the same polarity as those of the n-type selection regions 56a and 56b. Electrons are thereby induced near the interfaces of the n-type selection regions 56a and 56b facing the first insulating film 61, and the width W7 of the p-n junction depletion layer D7 is reduced. Therefore, a dark current generated in the depletion layer D7 can be reduced.

According to the light receiving element according to the fourth embodiment, even in a case where the configuration has reverse polarities of the polarities of the light receiving element according to the first embodiment, advantages similar to the advantages of the light receiving element according to the first embodiment are attained by making the fixed electric charge of the first insulating film 61 a reverse polarity as well. Note that although not depicted, even in a case where the configuration has reverse polarities of the polarities of the light receiving elements according to the second and third embodiments, advantages similar to the advantages of the light receiving elements according to the second and third embodiments are attained by making the fixed electric charge of the first insulating film 61 a reverse polarity as well.

### Fifth Embodiment

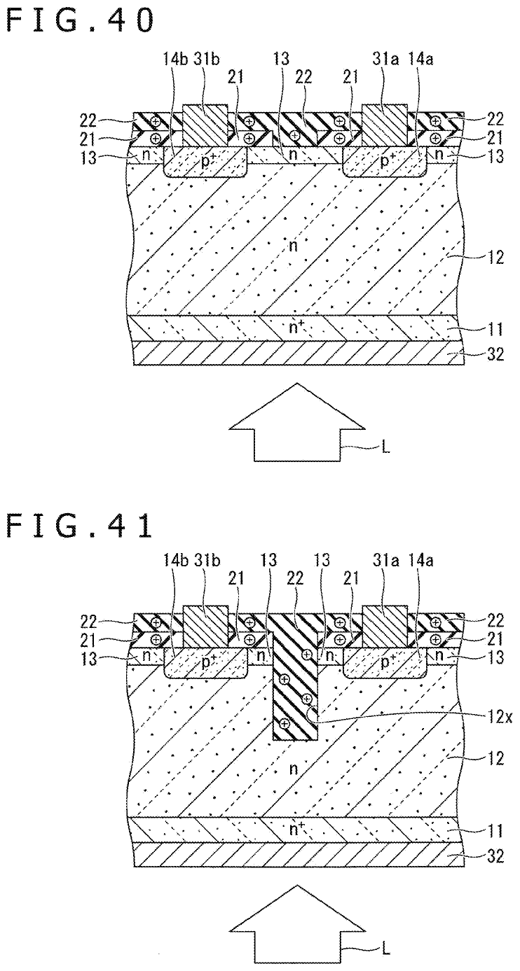

As depicted in FIG. 40, the basic configuration of the light receiving element according to the fifth embodiment is similar to the configuration according to the first embodiment depicted in FIG. 4. However, the basic configuration of the light receiving element according to the fifth embodiment is different from that in the first embodiment in that the second insulating film 22 contacts the semiconductor layer 13.

In a case where the selection regions 14a and 14b contact the first electrodes 31a and 31b and additionally the charge density of the selection regions 14a and 14b is higher than the charge density of the semiconductor layer 13, the second insulating film 22 preferably has a fixed electric charge with the same polarity as the polarities of the first insulating film 21 and selection regions 14a and 14b. For example, as depicted in FIG. 40, in a case where the selection regions 14a and 14b have a p-type polarity, the second insulating film 22 preferably has positive fixed electric charges (holes). Electrons are thereby induced at the interface of the n-type semiconductor layer 13 facing the second insulating film 22, and a dark current generated at the interface between the semiconductor layer 13 and the second insulating film 22 can be reduced. Note that the second insulating film 22 may have negative fixed electric charges (electrons) or may not have fixed electric charges.

In addition, although not depicted, in a case where the entire configuration is reversed and the selection regions 14a and 14b have an n-type polarity, the second insulating film 22 preferably has negative fixed electric charges (electrons). Holes are thereby induced at the interface of the p-type semiconductor layer 13 facing the second insulating film 22, and a dark current generated at the interface between the semiconductor layer 13 and the second insulating film 22 can be reduced. Note that in a case where the charge density of the selection regions 14a and 14b is lower than the charge density of the semiconductor layer 13, the second insulating film 22 preferably has a fixed electric charge with reverse polarity of the polarity of the first insulating film 21.

According to the light receiving element according to the fifth embodiment, in a case where the selection regions 14a and 14b contact the first electrodes 31a and 31b, because the second insulating film 22 contacting the semiconductor layer 13 has a fixed electric charge with the same polarity as the polarities of the selection regions 14a and 14b, a dark current generated at the interface between the semiconductor layer 13 and the second insulating film 22 can be reduced.

### Sixth Embodiment

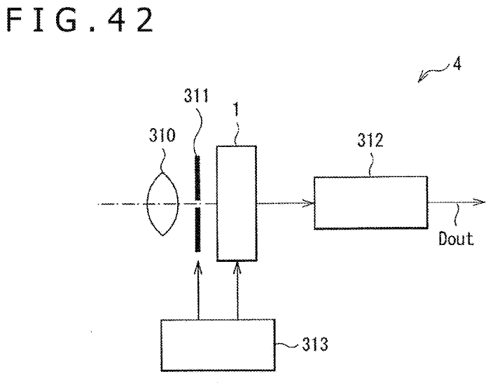

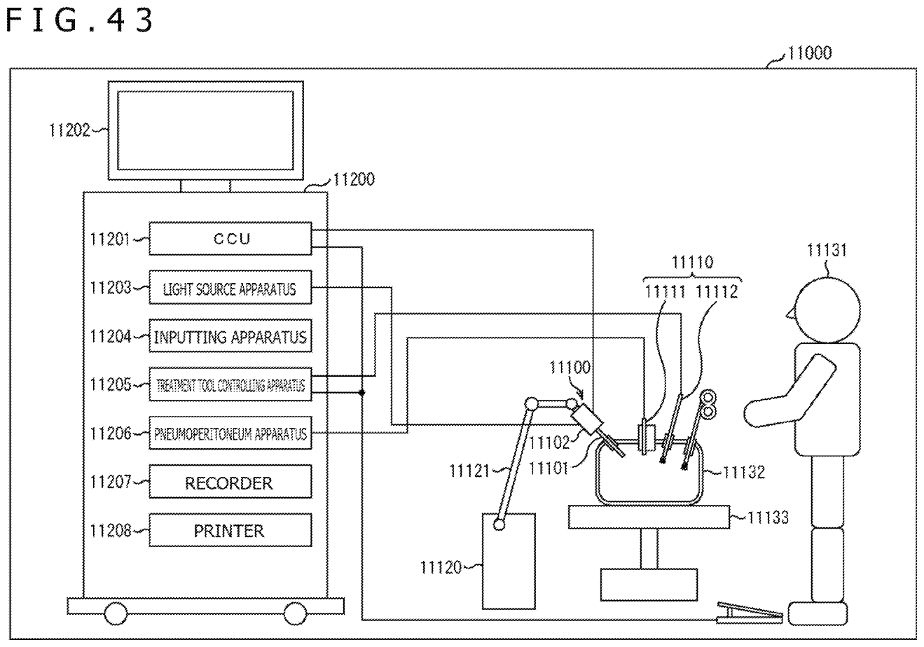

As depicted in FIG. 41, a light receiving element according to a sixth embodiment is different from the configuration in the fifth embodiment depicted in FIG. 40 in that a trench 12x is provided between the pixels P. Because, in other respects, the configuration of the light receiving element according to the sixth embodiment is similar to the configuration of the fifth embodiment depicted in FIG. 40, an overlapping explanation is omitted.

The trench 12x is provided in such a manner as to penetrate the semiconductor layer 13 from the second surface (upper surface) of the semiconductor layer 13, the second surface being opposite to the first surface (lower surface) on the side of the light absorption layer 12, and to reach a part of the light absorption layer 12 in the depth direction. Note that the trench 12x may penetrate the semiconductor layer 13 and the light absorption layer 12 and reach the semiconductor layer 11. The trench 12x has a grid-like planar pattern such that the trench 12x functions as a partition between the pixels P.

According to the light receiving element according to the sixth embodiment, because the trench 12x is formed, the pixels P can be separated. Further, in a case where the selection regions 14a and 14b contact the first electrodes 31a and 31b, because the second insulating film 22 contacting the semiconductor layer 13 has a fixed electric charge with the same polarity as the polarities of the selection regions 14a and 14b, a dark current generated at the interface between the semiconductor layer 13 and the second insulating film 22 can be reduced.

### Other Embodiments

The present technology has been described with reference to the first to sixth embodiments as described above, but statements and figures included as a part of the disclosure should not be understood to limit the present technology. If the gist of the technical content disclosed by the embodiments described above is understood, it will be apparent for those skilled in the art that various alternative embodiments, implementation examples, and operational technologies can be included in the present technology. In addition, the configuration disclosed by each of the first to fifth embodiments and modification examples thereof can be combined with each other as appropriate within the scope to the extent that such a combination does not cause a contradiction. For example, the configuration disclosed by each of a plurality of different embodiments may be combined with each other, or the configuration disclosed by each of a plurality of different modification examples of the same embodiment may be combined with each other.

### Application Examples

For example, the solid-state image pickup apparatus 1 can be applied to various types of electronic equipment such as a camera that can capture images in the infrared region. For example, as depicted in FIG. 42, electronic equipment 4 is included in a camera that can capture still images or moving images. The electronic equipment 4 includes the solid-state image pickup apparatus 1, an optical system (optical lens) 310, a shutter apparatus 311, a driving section 313, and a signal processing section 312.

The optical system 310 guides image light (incident light) from a subject to the solid-state image pickup apparatus 1. The optical system 310 may include a plurality of optical lenses. The shutter apparatus 311 controls a period during which the solid-state image pickup apparatus 1 is irradiated with light and a period during which the solid-state image pickup apparatus 1 is blocked from light. The driving section 313 controls transfer operation of the solid-state image pickup apparatus 1 and shutter operation of the shutter apparatus 311. The signal processing section 312 performs various types of signal processing on signals output from the solid-state image pickup apparatus 1. A video signal Dout having been subjected to the signal processing is stored on a storage medium such as a memory or is output to a monitor or the like.

### Examples of Application to Endoscopic Surgery Systems

The technology according to the present disclosure (the present technology) can be applied to various products. For example, the technology according to the present disclosure may be applied to endoscopic surgery systems.

FIG. 43 is a view depicting an example of a schematic configuration of an endoscopic surgery system to which the technology according to an embodiment of the present disclosure (present technology) can be applied.

In FIG. 43, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

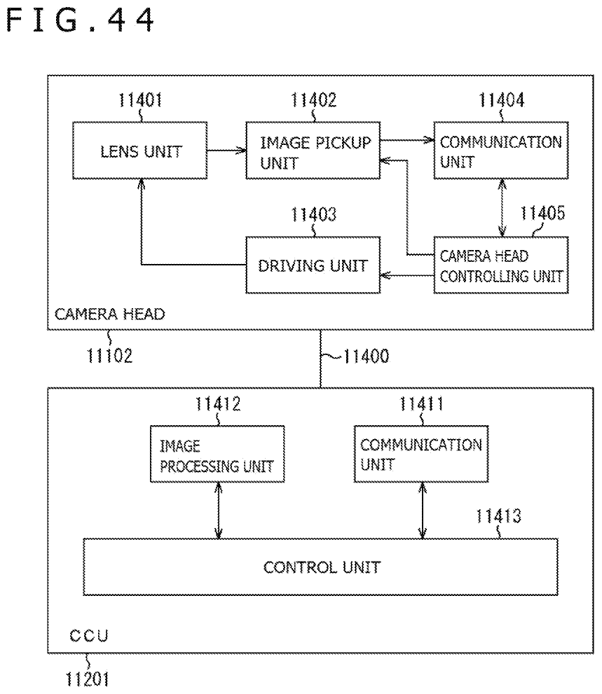

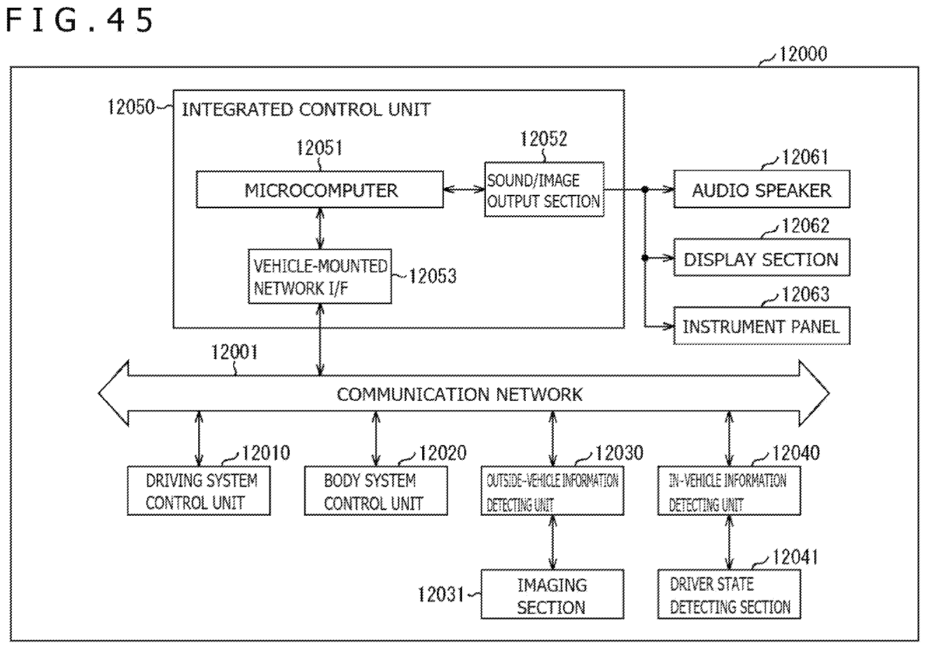

FIG. 44 is a block diagram depicting an example of a functional configuration of the camera head 11102 and the CCU 11201 depicted in FIG. 43.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of endoscopic surgery systems to which the technology according to the present disclosure can be applied has been explained thus far. The present technology can be applied the image pickup unit 11402 in the configuration explained above. By applying the present technology to the image pickup unit 11402, a clearer image of a surgical region can be obtained. Therefore, it becomes possible for a surgeon to surely check the surgical region.

Note that whereas an endoscopic surgery system is explained as an example here, the present technology may be applied to others, for example, to microscopic surgery systems and the like.

### Examples of Application to Mobile Bodies

The technology according to the present disclosure (the present technology) can be applied to various products. For example, the technology according to the present disclosure may be realized as an apparatus to be mounted on any type of mobile body such as a car, an electric car, a hybrid electric car, a motorcycle, a bicycle, a personal mobility, an airplane, a drone, a ship, or a robot.

FIG. 45 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 45, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12030 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 45, an audio speaker 12061, a display section 12062, and an instrument panel 12063 are illustrated as the output device. The display section 12062 may, for example, include at least one of an on-board display and a head-up display.

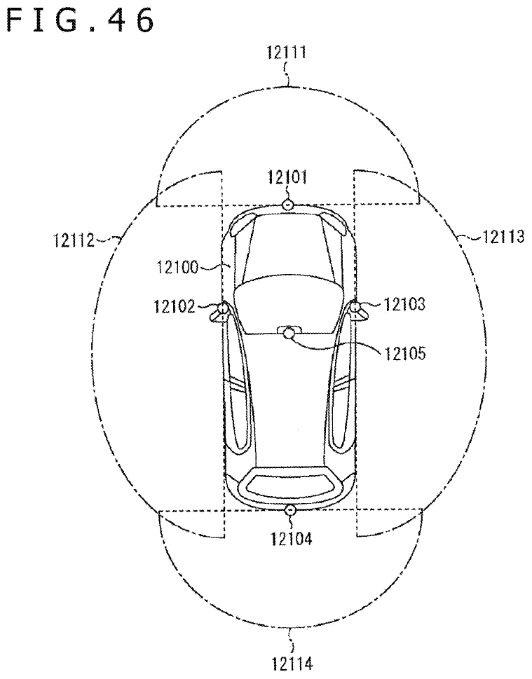

FIG. 46 is a diagram depicting an example of the installation position of the imaging section 12031.

In FIG. 46, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 46 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of vehicle control systems to which the present technology can be applied has been explained thus far. The present technology can be applied to the imaging section 12031 in the configurations explained above. By applying the technology according to the present disclosure to the imaging section 12031, captured images which are easily viewable can be obtained. Therefore, it becomes possible to mitigate the fatigue of a driver.

Further, the solid-state image pickup apparatus 1 according to the present technology can be applied also to electronic equipment such as monitoring cameras, biometric authentication systems, and thermography devices. For example, monitoring cameras are for night vision systems (night vision). By applying the solid-state image pickup apparatus 1 to a monitoring camera, it becomes possible to recognize, from a distant location, pedestrians, animals, and the like at night. In addition, if the solid-state image pickup apparatus 1 is applied as a vehicle-mounted camera, there is less influence of head lights and weather. For example, captured images can be obtained without being influenced by smoke, fog, or the like. Further, it becomes possible also to recognize the shapes of objects. In addition, in thermography, contactless temperature measurement becomes possible. In thermography, detection of temperature distributions and heat generation is also possible. Additionally, the solid-state image pickup apparatus 1 can be applied also to electronic equipment that senses flames, moisture content, gas, or the like.

Note that the present technology can have configuration like the configuration below.

(1)

A light receiving element including:

a plurality of pixels, in which each of the plurality of pixels includes
a light absorption layer that has a first surface from which light enters and that includes a compound semiconductor material,
a first-conductivity-type first semiconductor layer that is provided on a side of a second surface of the light absorption layer, the second surface being opposite to the first surface, and has bandgap energy greater than that of the light absorption layer,
a second-conductivity-type selection region that is provided in such a manner as to reach the light absorption layer from a second surface of the first semiconductor layer, the second surface being opposite to a first surface on a side of the light absorption layer, and contacts the first semiconductor layer,
a first insulating film that is provided on a side of the second surface of the first semiconductor layer and contacts the first semiconductor layer and the selection region, and
a first electrode provided, for each of the pixels, on the side of the second surface of the first semiconductor layer, and

the first insulating film has a non-volatile electric charge with a same polarity as that of one of the semiconductor layer and the selection region that has a higher mobile charge density.

(2)

The light receiving element according to (1), in which the selection region contacts the first electrodes.

(3)

The light receiving element according to (2), further including:
a second insulating film that is provided on the side of the second surface of the first semiconductor layer and contacts the first semiconductor layer.
   (4)

The light receiving element according to (3), in which a charge density of the selection region is higher than a charge density of the first semiconductor layer, and

the second insulating film has a non-volatile electric charge with a same polarity as that of the first insulating film.

(5)

The light receiving element according to (3) or (4), in which

a charge density of the selection region is lower than a charge density of the first semiconductor layer, and

the second insulating film has a non-volatile electric charge with a reverse polarity of a polarity of the first insulating film.

(6)

The light receiving element according to any one of (1) to (5), further including:

a first-conductivity-type second semiconductor layer that is provided on a side of the first surface of the light absorption layer and has bandgap energy greater than that of the light absorption layer.

(7)

The light receiving element according to (6), further including:

a second electrode provided on a second surface of the second semiconductor layer, the second surface being opposite to a first surface on a side of the light absorption layer.

(8)

The light receiving element according to any one of (1) to (7), in which a groove that reaches the light absorption layer from the second surface of the first semiconductor layer is provided between adjacent ones of the pixels.

(9)

The light receiving element according to (1), in which the selection region is positioned between the first electrodes each provided for each of the pixels.

(10)

The light receiving element according to (9), further including:

a second insulating film that is provided on the side of the second surface of the first semiconductor layer and contacts the selection region.

(11)

The light receiving element according to (10), in which a charge density of the selection region is higher than a charge density of the first semiconductor layer, and

the second insulating film has a non-volatile electric charge with a reverse polarity of a polarity of the first insulating film.

(12)

The light receiving element according to (10), in which a charge density of the selection region is lower than a charge density of the first semiconductor layer, and

the second insulating film has a non-volatile electric charge with a same polarity as that of the first insulating film.

(13)

The light receiving element according to any one of (9) to (12), further including:

between the side of the second surface of the light absorption layer and a side of the first surface of the first semiconductor layer, a second-conductivity-type second semiconductor layer having bandgap energy greater than that of the light absorption layer.

(14)

The light receiving element according to any one of (9) to (13), in which a groove that reaches the light absorption layer from the second surface of the first semiconductor layer is provided between adjacent ones of the pixels.

(15)

The light receiving element according to (14), in which the selection region is provided along the groove.

(16)

A light receiving element manufacturing method including:

forming a first-conductivity-type first semiconductor layer having bandgap energy greater than a light absorption layer that has a first surface from which light enters and that includes a compound semiconductor material, the first semiconductor layer being formed on a side of a second surface of the light absorption layer, the second surface being opposite to the first surface;

forming a second-conductivity-type selection region in such a manner as to reach the light absorption layer from a second surface of the first semiconductor layer, the second surface being opposite to a first surface on a side of the light absorption layer, and additionally contact the first semiconductor layer;

forming, on a side of the second surface of the first semiconductor layer, a first insulating film having a non-volatile electric charge with a same polarity as that of one of the first semiconductor layer and the selection region that has a higher mobile charge density such that the first insulating film contacts the first semiconductor layer and the selection region; and

forming, for each of the pixels, a first electrode on the side of the second surface of the first semiconductor layer.

(17)

The light receiving element manufacturing method according to (16), in which the selection region is formed by a diffusion process.

(18)

The light receiving element manufacturing method according to (16) or (17), in which the first electrode is formed in such a manner as to contact the selection region.

(19)

The light receiving element manufacturing method according to (16) or (17), in which the first electrode is formed in such a manner as to contact the first semiconductor layer.

(20)

A solid-state image pickup apparatus including:

a pixel region including a plurality of pixels; and

a circuit section that controls the pixel region, in which each of the plurality of pixels includes
a light absorption layer that has a first surface from which light enters and that includes a compound semiconductor material,
a first-conductivity-type first semiconductor layer that is provided on a side of a second surface of the light absorption layer, the second surface being opposite to the first surface, and has bandgap energy greater than that of the light absorption layer,
a second-conductivity-type selection region that is provided in such a manner as to reach the light absorption layer from a second surface of the first semiconductor layer, the second surface being opposite to a first surface on a side of the light absorption layer, and contacts the first semiconductor layer,
a first insulating film that is provided on a side of the second surface of the first semiconductor layer and contacts the first semiconductor layer and the selection region, and
a first electrode provided, for each of the pixels, on the side of the second surface of the first semiconductor layer, and

the first insulating film has a non-volatile electric charge with a same polarity as that of one of the semiconductor layer and the selection region that has a higher mobile charge density.

### REFERENCE SIGNS LIST

1: Solid-state image pickup apparatus
4: Electronic equipment
10A: Pixel region
11, 13, 51, 51a, 51b, 53, 53a, 53b, 54, 54a, 54b: Semiconductor layer
12, 52, 52a, 52b: Light absorption layer (photoelectric conversion layer)
12x, 50: Trench
14a, 14b, 55, 56a, 56b: Selection region
41 to 45: Photoresist film
130: Circuit section
131: Row scanning section
132: System controlling section
133: Horizontal selecting section
134: Column scanning section
135: Horizontal signal line
310: Optical system (optical lens)
311: Shutter apparatus
312: Signal processing section
313: Driving section
11000: Endoscopic surgery system
11100: Endoscope
11101: Lens barrel
11102: Camera head
11110: Surgical tool
11111: Pneumoperitoneum tube
11112: Energy device
11120: Supporting arm apparatus
11131: Surgeon (doctor)
11132: Patient
11133: Patient bed
11200: Cart
11202: Display apparatus
11203: Light source apparatus
11204: Inputting apparatus
11205: Treatment tool controlling apparatus
11206: Pneumoperitoneum apparatus
11207: Recorder
11208: Printer
11400: Transmission cable
11401: Lens unit
11402: Image pickup unit
11403: Driving unit
11404: Communication unit
11405: Camera head controlling unit
11411: Communication unit
11412: Image processing unit
11413: Controlling unit
12000: Vehicle control system
12001: Communication network
12010: Driving system control unit
12020: Body system control unit
12030: Outside-vehicle information detecting unit
12030: Body system control unit
12031: Imaging section
12040: In-vehicle information detecting unit
12041: Driver state detecting section
12050: Integrated control unit
12051: Microcomputer
12052: Sound/image output section
12061: Audio speaker
12062: Display section
12063: Instrument panel
12100: Vehicle
12101 to 12105: Imaging section
P: Pixel

1. A light receiving element comprising:
a plurality of pixels, wherein
each of the plurality of pixels includes
a light absorption layer that has a first surface from which light enters and that includes a compound semiconductor material,
a first-conductivity-type first semiconductor layer that is provided on a side of a second surface of the light absorption layer, the second surface being opposite to the first surface, and has bandgap energy greater than that of the light absorption layer,
a second-conductivity-type selection region that is provided in such a manner as to reach the light absorption layer from a second surface of the first semiconductor layer, the second surface being opposite to a first surface on a side of the light absorption layer, and contacts the first semiconductor layer,
a first insulating film that is provided on a side of the second surface of the first semiconductor layer and contacts the first semiconductor layer and the selection region, and
a first electrode provided, for each of the pixels, on the side of the second surface of the first semiconductor layer, and
the first insulating film has a non-volatile electric charge with a same polarity as that of one of the semiconductor layer and the selection region that has a higher mobile charge density.

2. The light receiving element according to claim 1, wherein the selection region contacts the first electrodes.

3. The light receiving element according to claim 2, further comprising:
a second insulating film that is provided on the side of the second surface of the first semiconductor layer and contacts the first semiconductor layer.

4. The light receiving element according to claim 3, wherein
a charge density of the selection region is higher than a charge density of the first semiconductor layer, and
the second insulating film has a non-volatile electric charge with a same polarity as that of the first insulating film.

5. The light receiving element according to claim 3, wherein
a charge density of the selection region is lower than a charge density of the first semiconductor layer, and
the second insulating film has a non-volatile electric charge with a reverse polarity of a polarity of the first insulating film.

6. The light receiving element according to claim 1, further comprising:
a first-conductivity-type second semiconductor layer that is provided on a side of the first surface of the light absorption layer and has bandgap energy greater than that of the light absorption layer.

7. The light receiving element according to claim 6, further comprising:
a second electrode provided on a second surface of the second semiconductor layer, the second surface being opposite to a first surface on a side of the light absorption layer.

8. The light receiving element according to claim 1, wherein a groove that reaches the light absorption layer from the second surface of the first semiconductor layer is provided between adjacent ones of the pixels.

9. The light receiving element according to claim 1, wherein the selection region is positioned between the first electrodes each provided for each of the pixels.

10. The light receiving element according to claim 9, further comprising:
a second insulating film that is provided on the side of the second surface of the first semiconductor layer and contacts the selection region.

11. The light receiving element according to claim 10, wherein
a charge density of the selection region is higher than a charge density of the first semiconductor layer, and
the second insulating film has a non-volatile electric charge with a reverse polarity of a polarity of the first insulating film.

12. The light receiving element according to claim 10, wherein
a charge density of the selection region is lower than a charge density of the first semiconductor layer, and
the second insulating film has a non-volatile electric charge with a same polarity as that of the first insulating film.

13. The light receiving element according to claim 9, further comprising:
between the side of the second surface of the light absorption layer and a side of the first surface of the first semiconductor layer, a second-conductivity-type second semiconductor layer having bandgap energy greater than that of the light absorption layer.

14. The light receiving element according to claim 9, wherein a groove that reaches the light absorption layer from the second surface of the first semiconductor layer is provided between adjacent ones of the pixels.

15. The light receiving element according to claim 14, wherein the selection region is provided along the groove.

16. A light receiving element manufacturing method comprising:
forming a first-conductivity-type first semiconductor layer having bandgap energy greater than a light absorption layer that has a first surface from which light enters and that includes a compound semiconductor material, the first semiconductor layer being formed on a side of a second surface of the light absorption layer, the second surface being opposite to the first surface;
forming a second-conductivity-type selection region in such a manner as to reach the light absorption layer from a second surface of the first semiconductor layer, the second surface being opposite to a first surface on a side of the light absorption layer, and additionally contact the first semiconductor layer;
forming, on a side of the second surface of the first semiconductor layer, a first insulating film having a non-volatile electric charge with a same polarity as that of one of the first semiconductor layer and the selection region that has a higher mobile charge density such that the first insulating film contacts the first semiconductor layer and the selection region; and
forming, for each of the pixels, a first electrode on the side of the second surface of the first semiconductor layer.

17. The light receiving element manufacturing method according to claim 16, wherein the selection region is formed by a diffusion process.

18. The light receiving element manufacturing method according to claim 16, wherein the first electrode is formed in such a manner as to contact the selection region.

19. The light receiving element manufacturing method according to claim 16, wherein the first electrode is formed in such a manner as to contact the first semiconductor layer.

20. A solid-state image pickup apparatus comprising:
a pixel region including a plurality of pixels; and
a circuit section that controls the pixel region, wherein each of the plural pixels includes
a light absorption layer that has a first surface from which light enters and that includes a compound semiconductor material,
a first-conductivity-type first semiconductor layer that is provided on a side of a second surface of the light absorption layer, the second surface being opposite to the first surface, and has bandgap energy greater than that of the light absorption layer,
a second-conductivity-type selection region that is provided in such a manner as to reach the light absorption layer from a second surface of the first semiconductor layer, the second surface being opposite to a first surface on a side of the light absorption layer, and contacts the first semiconductor layer,
a first insulating film that is provided on a side of the second surface of the first semiconductor layer and contacts the first semiconductor layer and the selection region, and
a first electrode provided, for each of the pixels, on the side of the second surface of the first semiconductor layer, and
the first insulating film has a non-volatile electric charge with a same polarity as that of one of the semiconductor layer and the selection region that has a higher mobile charge density.
